(19) United States
(12) Patent Application Publication
(10) Pub. No.: US 2024/0243192 A1
(43) Pub. Date: Jul. 18, 2024

(54) SEMICONDUCTOR DEVICE STRUCTURE INCLUDING FORKSHEET TRANSISTORS AND METHODS OF FORMING THE SAME

(71) Applicant: TAIWAN SEMICONDUCTOR MANUFACTURING COMPANY, LTD., Hsinchu (TW)

(72) Inventors: Ming-Heng TSAI, Taipei (TW); Chun-Sheng LIANG, Changhua (TW); Ta-Chun LIN, Hsinchu (TW); JHON JHY LIAW, Hsinchu (TW)

(21) Appl. No.: 18/096,389

(22) Filed: Jan. 12, 2023

(51) Int. Cl. H01L 29/775; H01L 29/06; H01L 29/08; H01L 29/423; H01L 29/66

(52) U.S. Cl. CPC H01L 29/775; H01L 29/0673; H01L 29/0847; H01L 29/42392; H01L 29/66439; H01L 29/66545

(57) ABSTRACT

A semiconductor device structure includes a dielectric wall disposed over a substrate, a plurality of first semiconductor layers vertically stacked and extended outwardly from a first side of the dielectric wall, a plurality of second semiconductor layers vertically stacked and extended outwardly from a second side of the dielectric wall, a first epitaxial source/drain (S/D) feature disposed on the first side of the dielectric wall, a second epitaxial S/D feature disposed on the second side of the dielectric wall, a first bottom dielectric layer extended outwardly from the first side of the dielectric wall, and a second bottom dielectric layer extended outwardly from the second side of the dielectric wall.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, transistors using nanowire channels have been proposed to achieve increased device density, greater carrier mobility and drive current in a device. As device size reduces, there is a continuous need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2 are perspective views of various stages of manufacturing a semiconductor device structure, in accordance with some embodiments.

FIGS. 3A-9A and 11A-16A are cross-sectional side views of various stages of manufacturing the semiconductor device structure taken along line A-A of FIG. 3C, in accordance with some embodiments.

FIGS. 3B-9B and 11B-12B are cross-sectional side views of various stages of manufacturing the semiconductor device structure taken along line B-B of FIG. 3C, in accordance with some embodiments.

FIG. 16B is a cross-sectional side view of the semiconductor device structure taken along line B-B of FIG. 12C, showing a stage after the formation of the first and second gate electrode layers, in accordance with some embodiments.

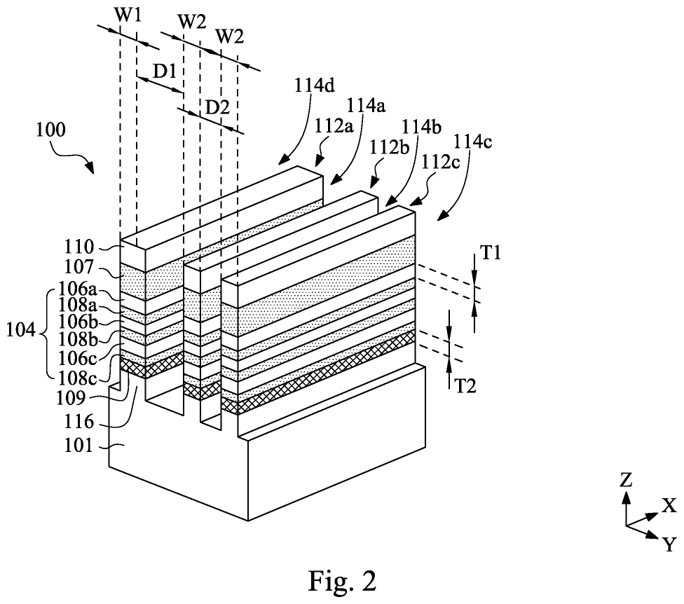

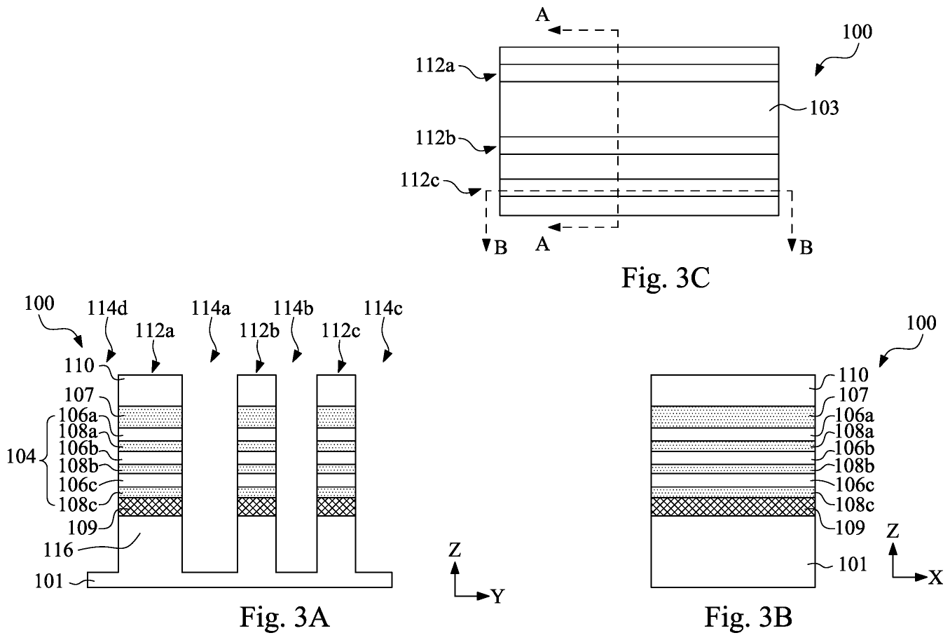

FIGS. 3C-9C and 11C-12C are top views of various stages of manufacturing the semiconductor device structure of FIG. 2 in accordance with some embodiments.

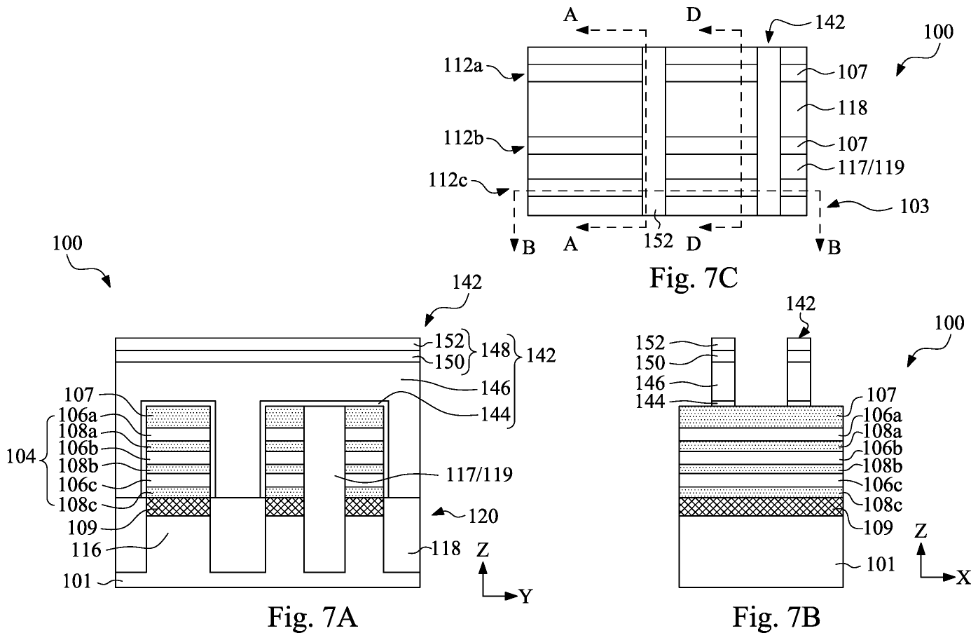

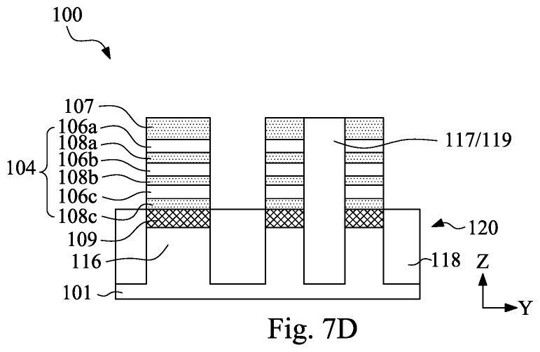

FIGS. 7D-9D and 11D-12D are cross-sectional side views of various stages of manufacturing the semiconductor device structure taken along line D-D of FIG. 7C, in accordance with some embodiments.

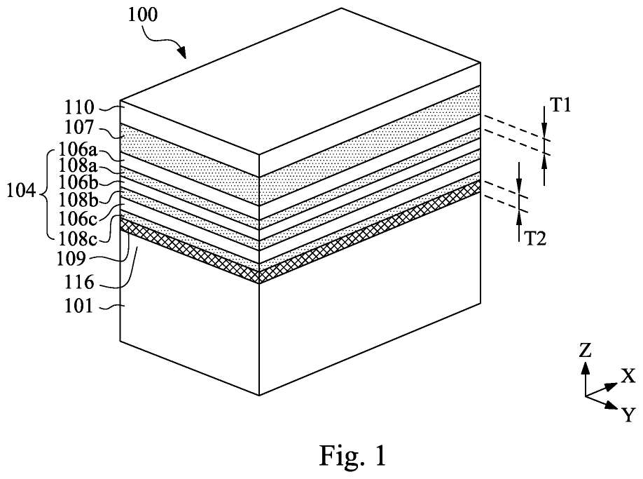

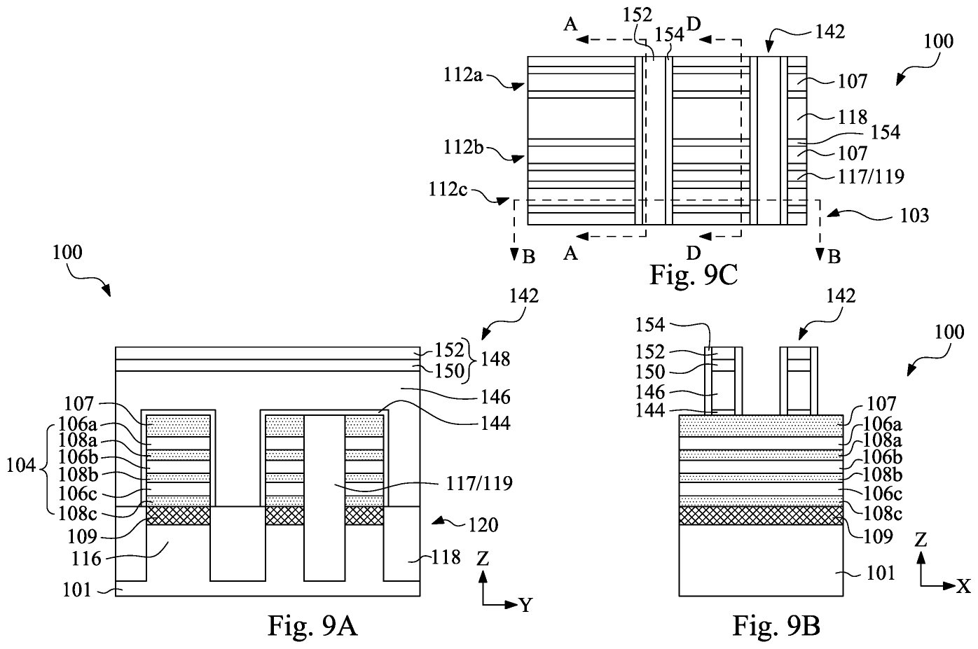

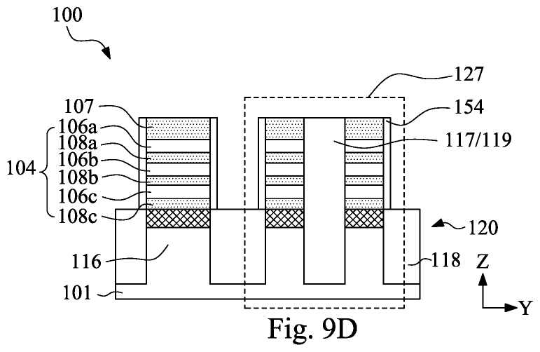

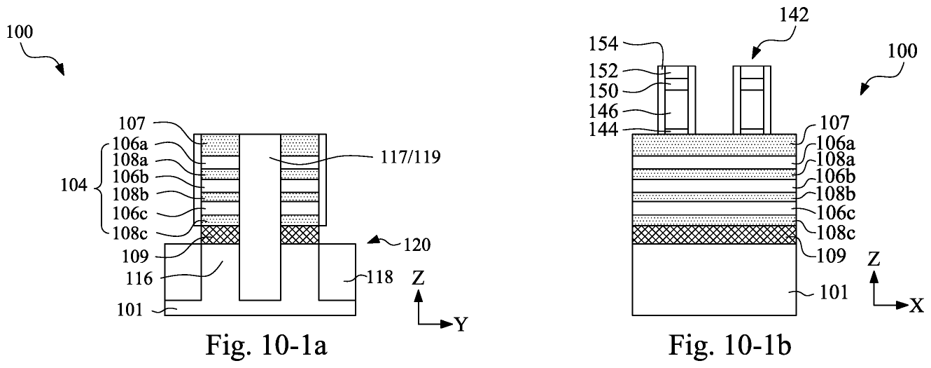

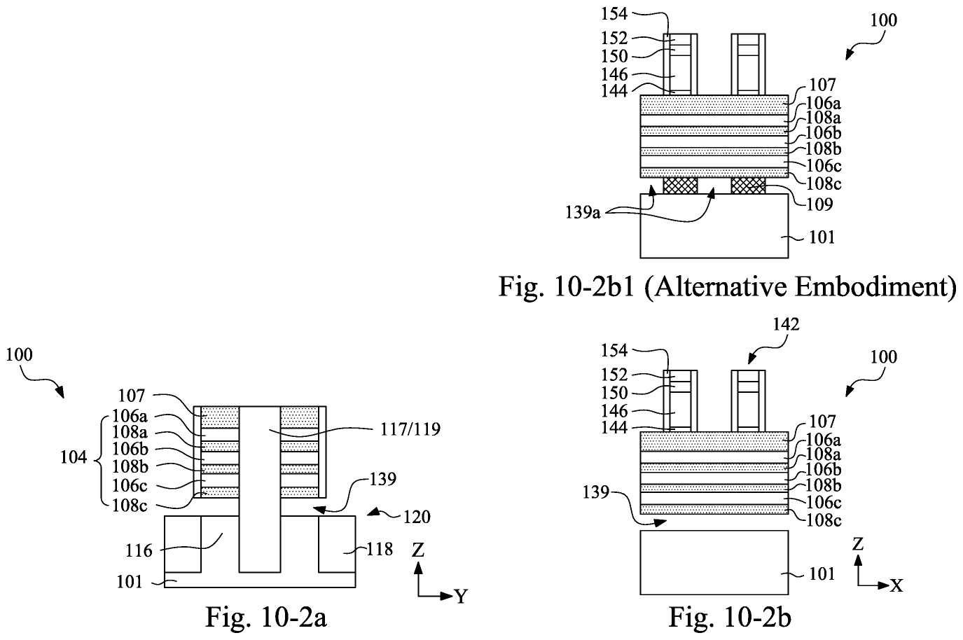

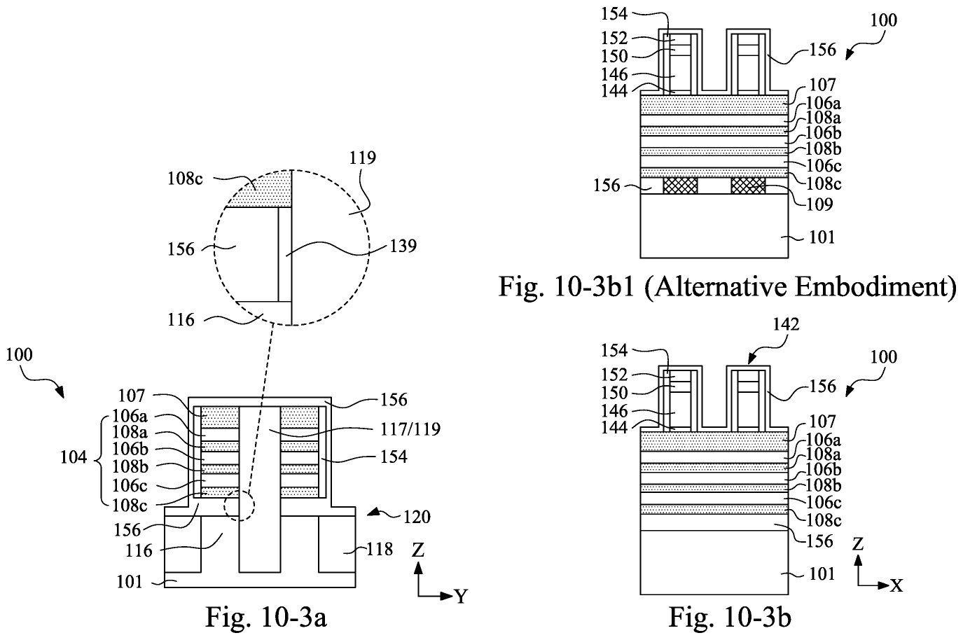

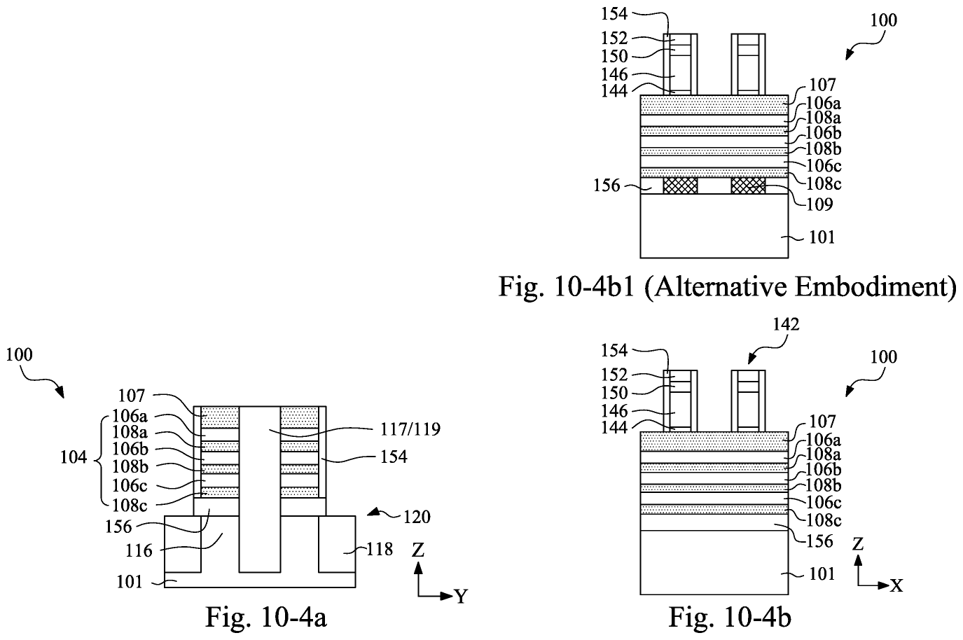

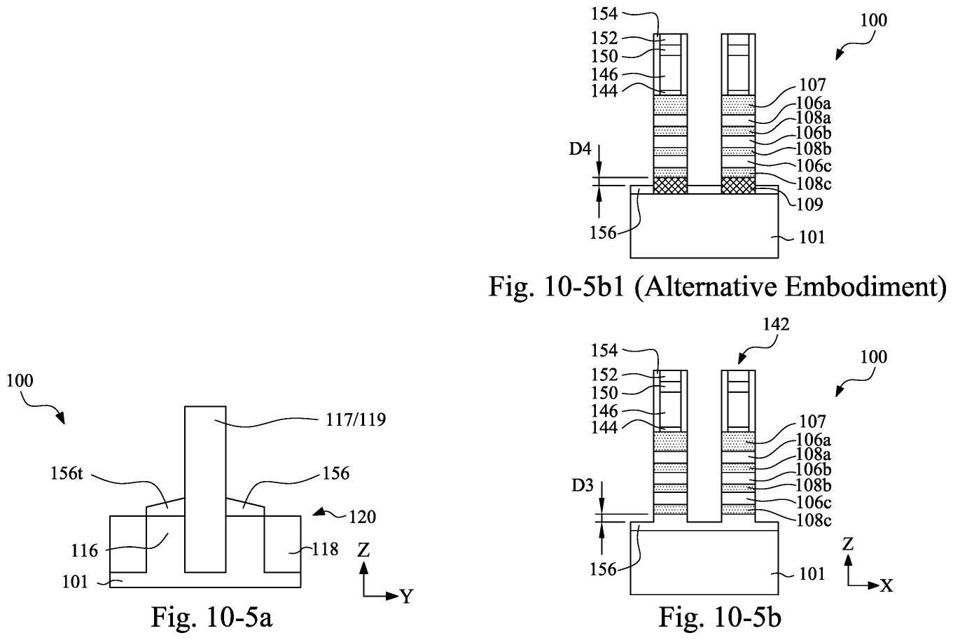

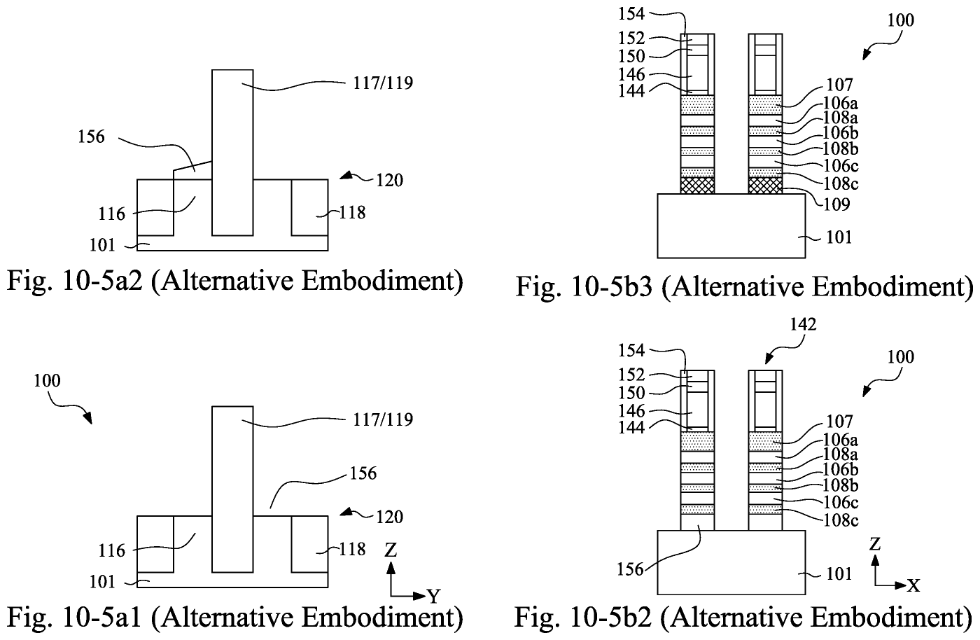

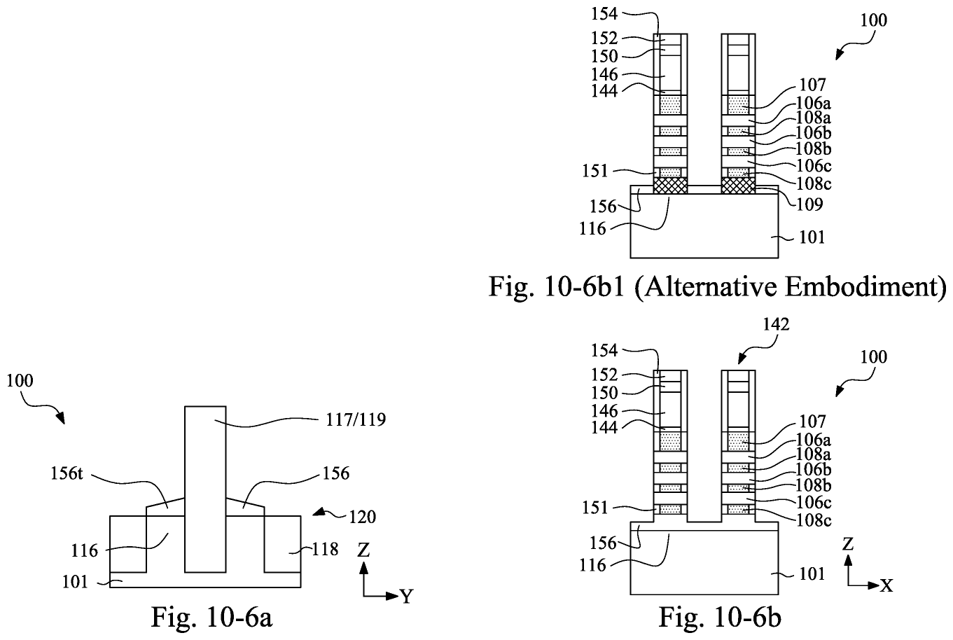

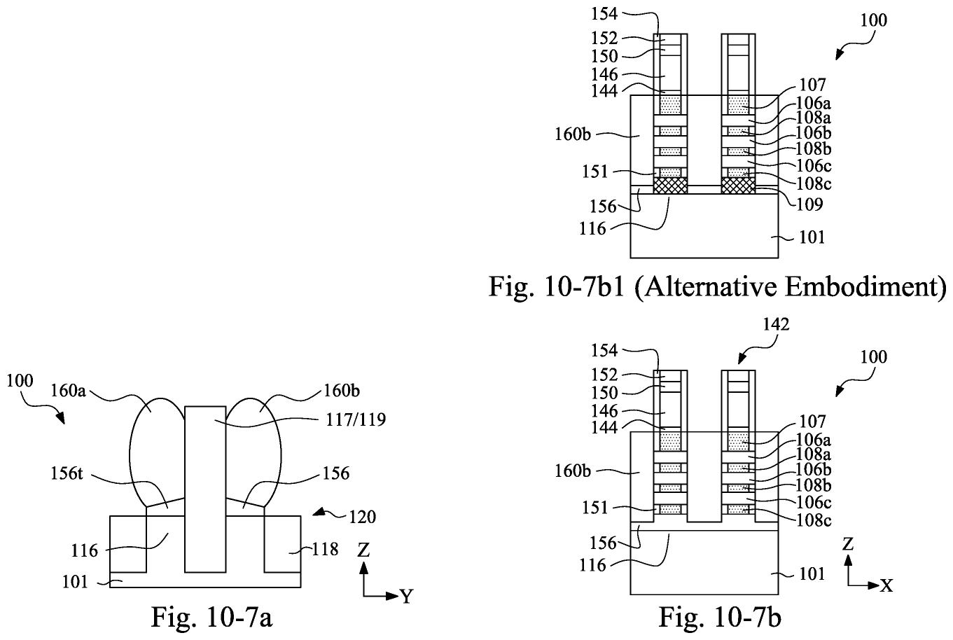

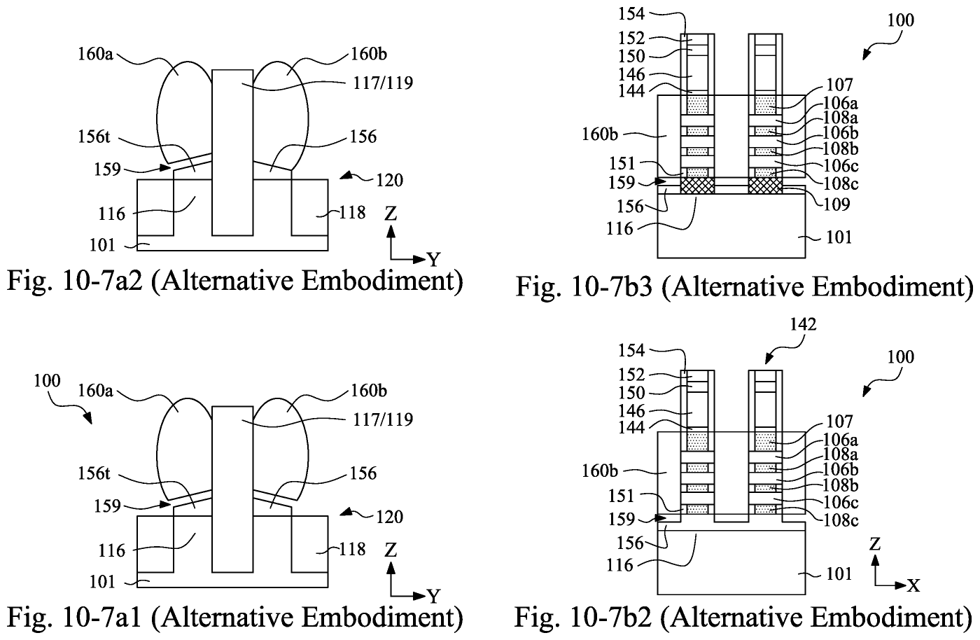

FIGS. 10-1a to 10-7a are cross-sectional side views of a portion of the semiconductor device structure in FIG. 9D showing various stages of manufacturing, in accordance with some embodiments.

FIGS. 10-1b to 10-7b are cross-sectional side views of the semiconductor device structure in FIG. 9B showing various stages of manufacturing, in accordance with some embodiments.

FIGS. 10-2b1, 10-3b1, 10-4b1, 10-5a1, 10-5b1, 10-5a2, 10-5b2, 10-5b3, 10-6b1, 10-7a1, 10-7b1, 10-7a2, 10-7b2, and 10-7b3 are cross-sectional side views of the semiconductor device structure in accordance with some alternative embodiments.

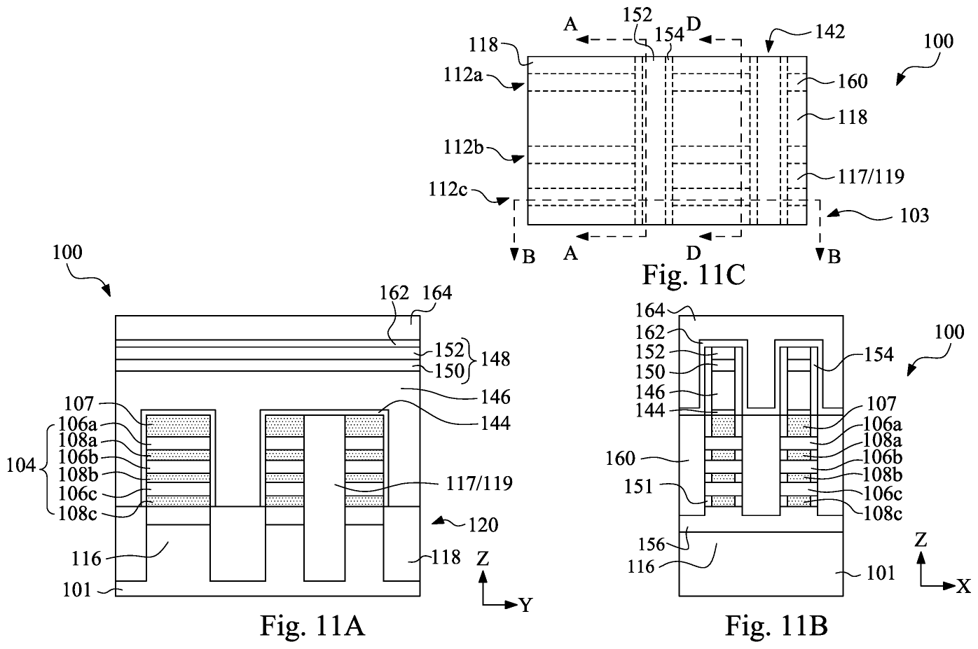

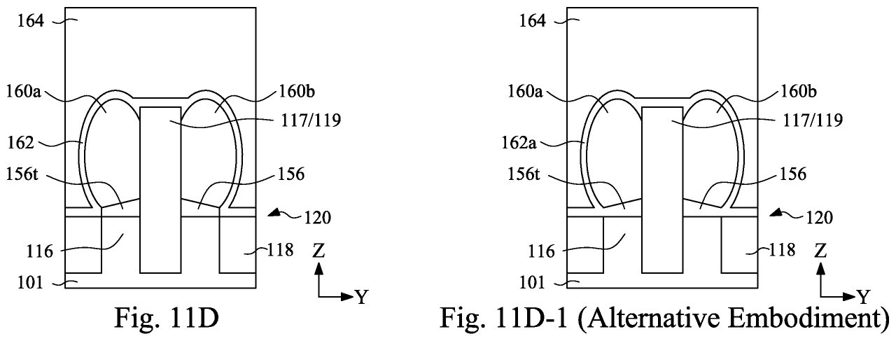

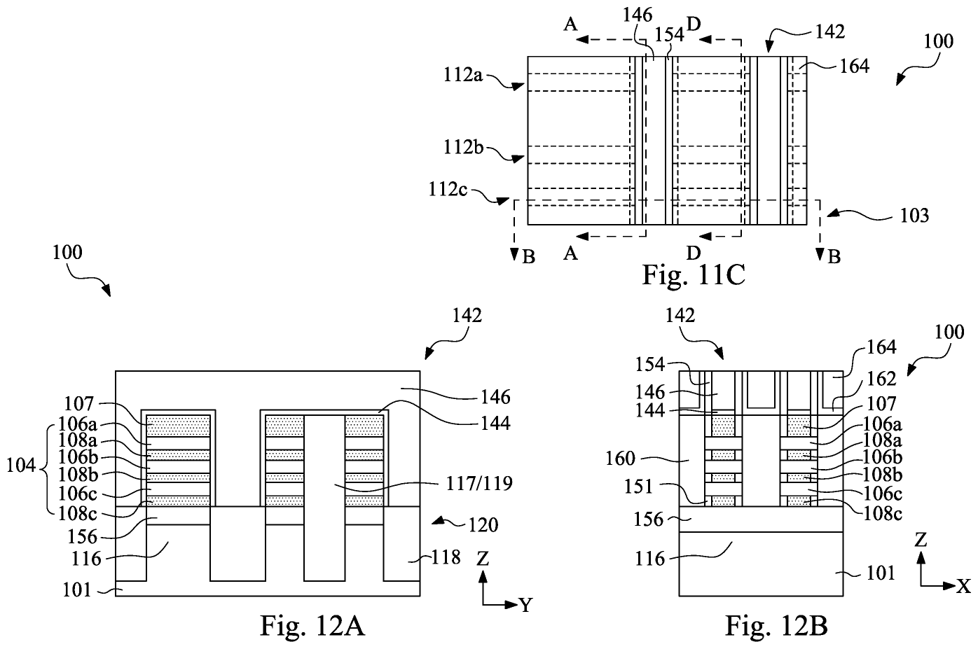

FIG. 11D-1 is a cross-sectional side view of the semiconductor device structure in accordance with some alternative embodiments.

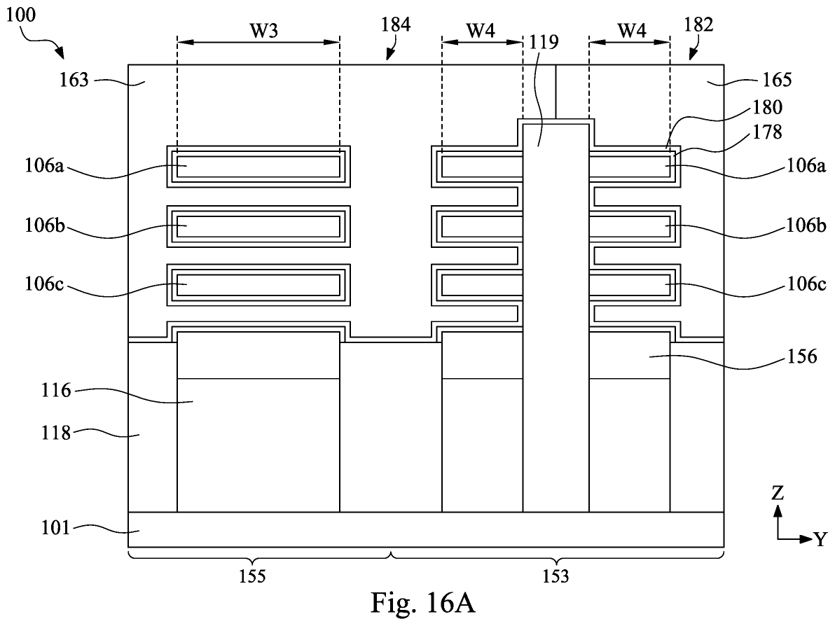

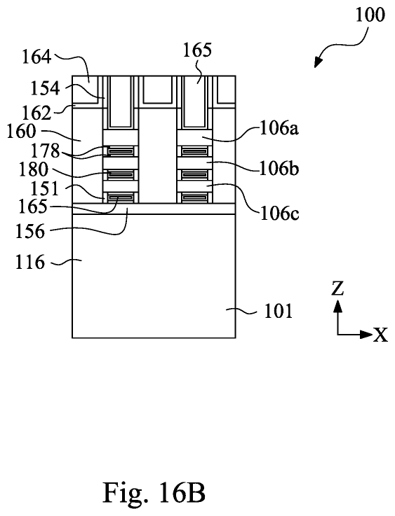

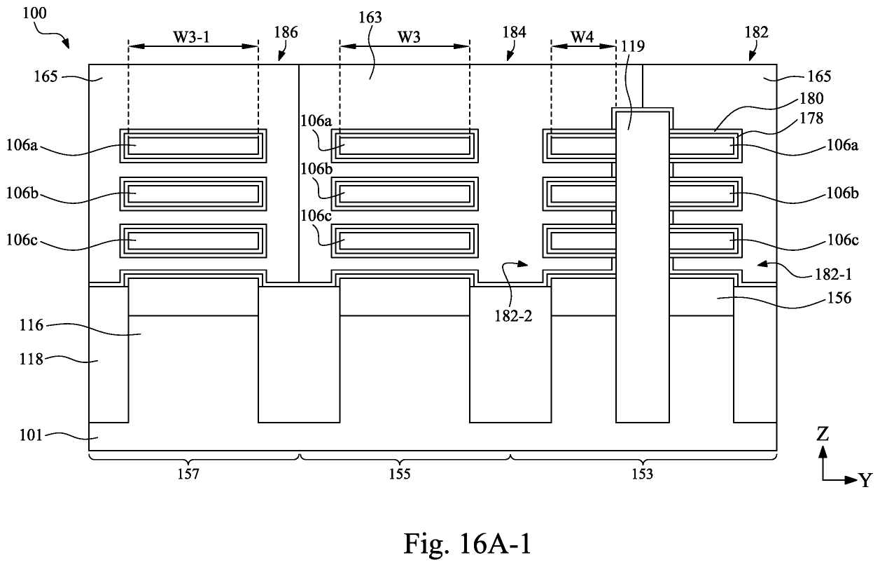

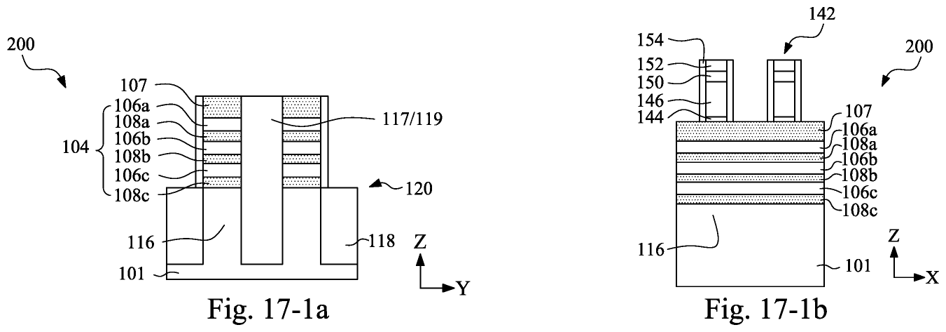

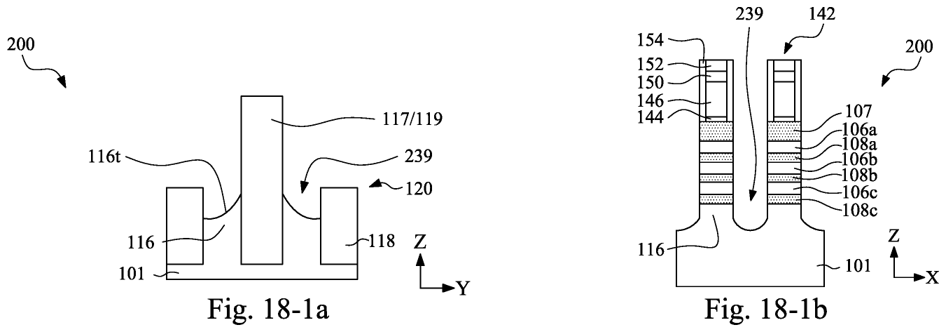

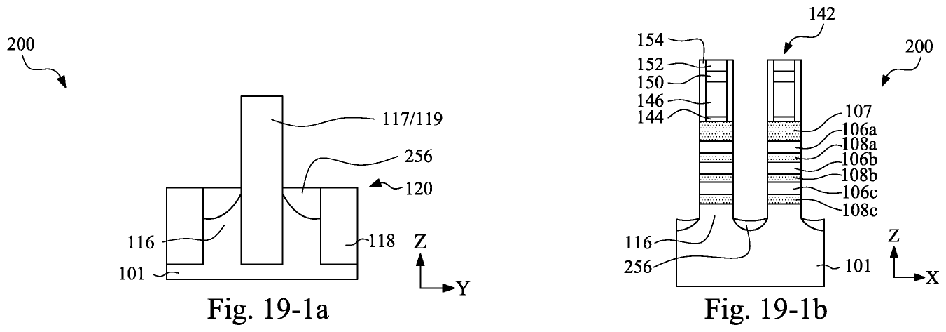

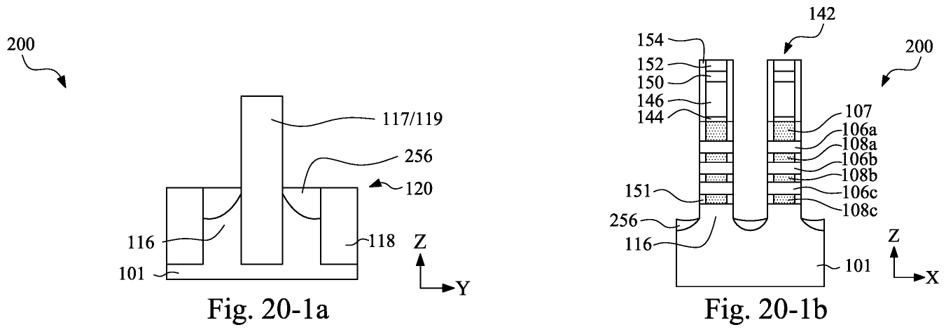

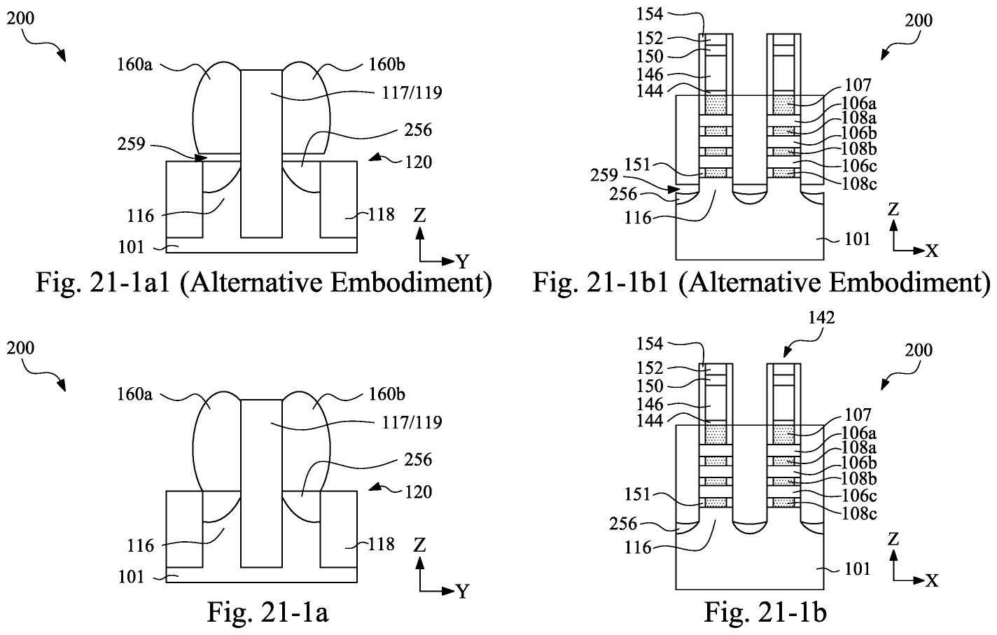

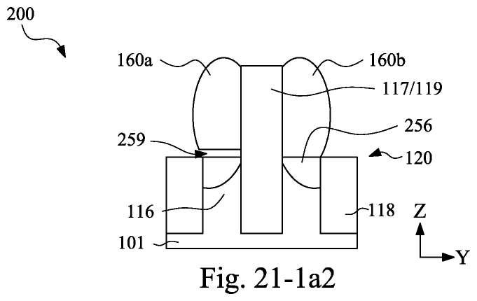

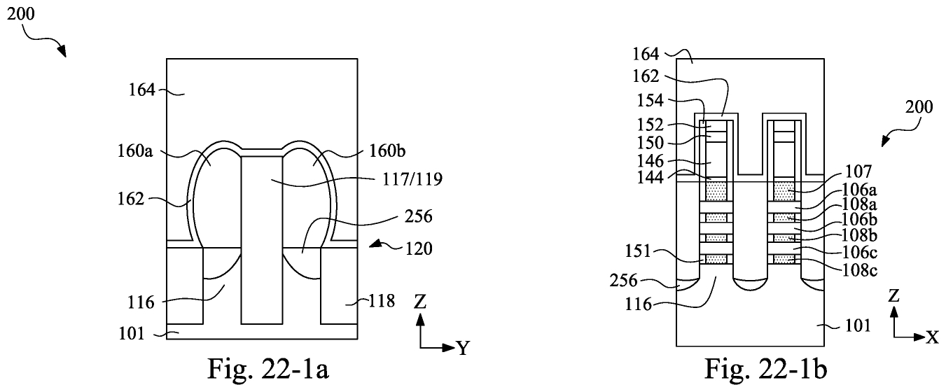

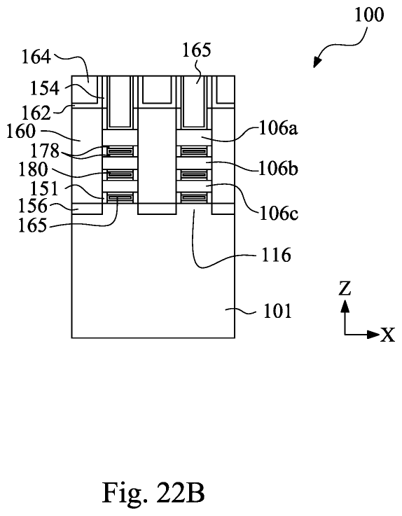

FIG. 16A-1 illustrates a cross-sectional view of the semiconductor device structure in accordance with some embodiments.

FIGS. 17-1a to 22-1a are cross-sectional side views of various stages of manufacturing a semiconductor device structure taken along a plane in the source/drain region, in accordance with some alternative embodiments.

FIGS. 17-1b to 22-1b are cross-sectional side views of various stages of manufacturing the semiconductor device structure taken along a plane in the fin structure, in accordance with some alternative embodiments.

FIGS. 21-1a1, 21-1b1, and 21-1a2 are cross-sectional side views of the semiconductor device structure in accordance with some alternative embodiments.

FIG. 22B is a cross-sectional side view of the semiconductor device structure taken along plane in the fin structure, showing a stage after the formation of the first and second gate electrode layers, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

FIGS. 1-22-1b show exemplary sequential processes for manufacturing a semiconductor device structure 100, in accordance with some embodiments. It is understood that additional operations can be provided before, during, and after processes shown by FIGS. 1-22-1b, and some of the operations described below can be replaced or eliminated, for additional embodiments of the method. The order of the operations/processes may be interchangeable.

FIG. 1 is a perspective view of one of various stages of manufacturing the semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a single crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 101 is made of Si. In some embodiments, the substrate 101 is a silicon-on-insulator (SOI) substrate, which includes an insulating layer (not shown) disposed between two silicon layers. In one aspect, the insulating layer is an oxide.

The substrate 101 may include various regions that have been doped with impurities (e.g., dopants having p-type or n-type conductivity). Depending on circuit design, the dopants may be, for example boron for a p-type (or p-channel) field effect transistor (FET) and phosphorus for an n-type (or n-channel) FET.

The stack of semiconductor layers 104 includes alternating semiconductor layers made of different materials to facilitate formation of nanosheet channels in a multi-gate device, such as nanosheet channel FETs or forksheet FETs. In some embodiments, the stack of semiconductor layers 104 includes first semiconductor layers 106 (106a-106c) and second semiconductor layers 108 (108a-108c). In some embodiments, the stack of semiconductor layers 104 includes alternating first and second semiconductor layers 106, 108. The first semiconductor layers 106 are aligned with the second semiconductor layers 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some cases, the SiGe in the first or second semiconductor layers 106, 108 can have a germanium atomic percentage between about 5 at. % and about 80 at. %, for example about 10 at. % to about 35 at. %. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. For example, the nanosheet channel(s) of a forksheet transistor may have at least three surfaces surrounded by the gate electrode. The semiconductor device structure 100 may include a nanosheet transistor and/or a forksheet transistor. The nanosheet transistors may be referred to as nanowire transistors, gate-all-around (GAA) transistors, multi-bridge channel (MBC) transistors, or any transistors having the gate electrode surrounding the channels.

It is noted that while three layers of the first semiconductor layers 106 and three layers of the second semiconductor layers 108 are alternately arranged as illustrated in FIG. 1, it can be appreciated that any number of first and second semiconductor layers 106, 108 can be formed in the stack of semiconductor layers 104, depending on the predetermined number of channels for the semiconductor device structure 100. In some embodiments, the number of first semiconductor layers 106, which is the number of channels, is between 2 and 8.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The substrate 101 may include a first sacrificial layer 107 on the stack of semiconductor layers 104. The first sacrificial layer 107 protects the stack of semiconductor layers 104 during the subsequent processes and is removed prior to formation of the gate stack. In cases where the first semiconductor layer 106 of the stack of semiconductor layers 104 is Si, the first sacrificial layer 107 includes SiGe epitaxially grown on the first semiconductor layer 106.

Each first semiconductor layer 106 may have a thickness T1 in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. The second semiconductor layers 108 may eventually be removed and serve to define a vertical distance between adjacent channels for the semiconductor device structure 100. The first sacrificial layer 107 may have a thickness that is equal, less, or greater than the thickness of the first semiconductor layer 106. The thickness of the first sacrificial layer 107 may range from about 2 nm to 50 nm. The thickness of the first semiconductor layer 106, the second semiconductor layer 108, and the first sacrificial layer 107 may vary depending on the application and/or device performance considerations.

A mask structure 110 is formed over the first sacrificial layer 107. The mask structure 110 may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The mask structure 110 may be formed by any suitable deposition process, such as chemical vapor deposition (CVD) process.

In some embodiments, the substrate 101 may include a second sacrificial layer 109 disposed upon bulk silicon or a well portion 116 formed from the substrate 101. In one example, the second sacrificial layer 109 is disposed in contact with the bottommost second semiconductor layer 108 (e.g., second semiconductor layer 108c). As will be discussed in more detail below, the second sacrificial layer 109 is to be replaced with a bottom dielectric material (156, FIGS. 10-3a and 10-3b), which separates the source/drain epitaxial features from the planar channel region for leakage prevention. In some embodiments, the second sacrificial layer 109 is a silicon-containing layer, such as silicon germanium, amorphous silicon (a—Si), silicon oxide, or the like. In some embodiments, the second sacrificial layer 109 may include the same material as the second semiconductor layer 108 but with different etch selectivity and/or oxidation rates. It has been observed that the second sacrificial layer 109 having higher germanium atomic percentage will have higher etch rates than the second semiconductor layers 108 having lower germanium atomic percentage. In cases where both second sacrificial layer 109 and the second semiconductor layers 108 are formed of SiGe, the atomic percentage of SiGe of the second sacrificial layer 109 can be selected to vary the etch rate of the second sacrificial layers 109 with the etchant, thereby removing the second sacrificial layer 109 while selectively preserving the second semiconductor layers 108 between the first semiconductor layers 106. In various embodiments, the second sacrificial layer 109 has a first atomic percentage and the second semiconductor layer 108 has a second atomic percentage lower than the first atomic percentage. In some embodiments, the second sacrificial layer 109 is silicon germanium having a germanium atomic percentage in a range of about 35 at. % to about 65 at. %, and the second semiconductor layer 108 is silicon germanium having a germanium atomic percentage in a range of about 5 at. % to about 30 at. %. In one exemplary embodiment, the second sacrificial layer 109 is silicon germanium having a germanium atomic percentage of about 50 at. % and the second semiconductor layer 108 is silicon germanium having a germanium atomic percentage of about 25 at. %. The second sacrificial layer 109 may have a thickness greater than that of the second semiconductor layer 108. In one embodiment, the second sacrificial layer 109 has a thickness T2 in a range of about 5 nm to about 55 nm.

FIG. 2 is a perspective view of one of the various stages of manufacturing the semiconductor device structure 100, in accordance with some embodiments. Fin structures 112 (112a-112c) are formed from the stack of semiconductor layers 104. Each fin structure 112 has an upper portion including the semiconductor layers 106, 108 and the well portion 116. The fin structures 112 may be fabricated using multi-patterning operations including photo-lithography and etching processes. The etching process can include dry etching, wet etching, reactive ion etching (RIE), and/or other suitable processes. The etching process forms trenches 114 (e.g., 114a, 114b, 114c, 114d) in unprotected regions through the mask structure 110, through the stack of semiconductor layers 104, and into the substrate 101, thereby leaving the plurality of extending fin structures 112 (e.g., 112a, 112b, 112c). The trenches 114 extend along the X direction. The trenches 114 may be etched using a dry etch (e.g., RIE), a wet etch, and/or combination thereof.

As shown in FIG. 2, the fin structure 112a may have a width W1, and the fin structures 112b, 112c may each has a width W2. The width W2 may be equal, less, or greater than the width W1. In one embodiment shown in FIG. 2, the width W1 is greater than the width W2. The widths W1, W2 may correspond to the device's channel width. In one embodiment, the width W1 is in a range between 5 nm to about 120 nm, for example about 10 nm to about 100 nm.

The distance between adjacent fin structures may be defined by the distance between a first sidewall of one fin structure and a second sidewall of the adjacent fin structure facing the first sidewall. For example, the fin structure 112a and the fin structure 112b are separated by a distance D1. The fin structure 112b and the fin structure 112c are separated by a distance D2. The distances D1, D2 may vary depending on the element layouts/application of the semiconductor device structure 100. The width of the fin structures 112a, 112b, 112c may also vary depending on the channel width of the devices needed in the semiconductor device structure 100. The devices with a wider channel, such as the devices to be fabricated from the fin structures 112a, 112b, may be more suitable for high-speed applications, such as a NAND device or high-performance computing (HPC). The devices with a narrower channel, such as the device fabricated from the fin structures 112b, 112c, may be more suitable for low-power and low-leakage applications, such as an inverter device or system-on-chip (SOC). Therefore, trenches with wider width (e.g., trench 114a) may be formed in regions where devices/transistors require higher voltage current and/or higher performance, while trenches with narrower width (e.g., trench 114b) may be formed in regions where greater density of devices/transistors is desired.

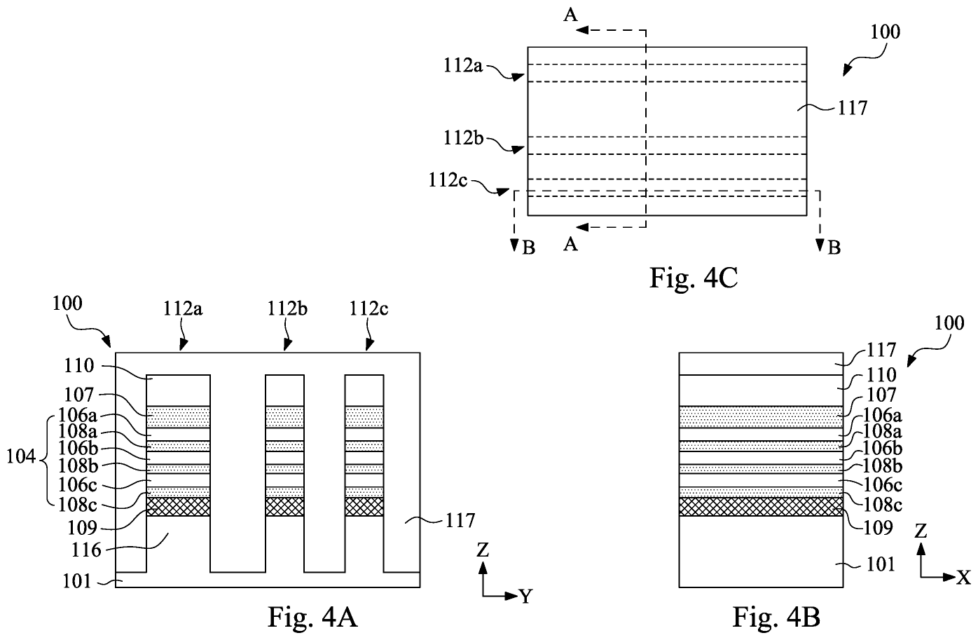

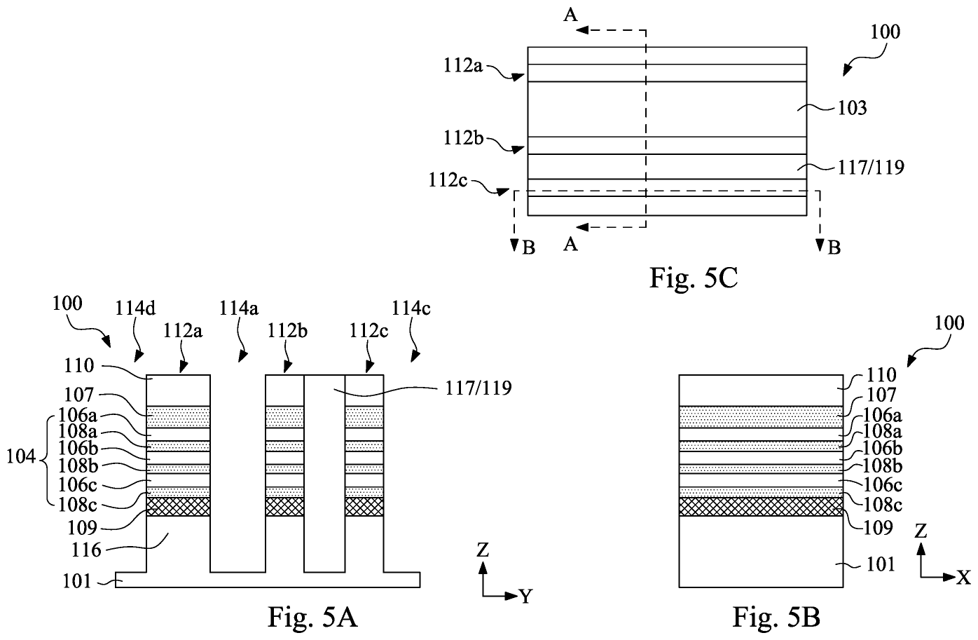

In one embodiment shown in FIG. 2, the first distance D1 is greater than the second distance D2. The distance D2 defines the width of the subsequent dielectric walls 119 (FIG. 5A). The second distance D2 may be in a range from about 2 nm to about 40 nm, for example about 3 nm to about 30 nm. With the smaller distance D2 (i.e., reduced fin-to-fin spacing) between the fin structures 112b and 112c, a subsequent insulating material 117 (FIG. 4A) may completely fill in the trench 114b before the dielectric material 117 fills up the trenches 114a, 114c, 114d. That is, trench 114a (and trenches 114c and 114d) remains open after the deposition of the dielectric material 117 due to the wider distance D1. The dielectric material 117 (later become dielectric wall 119) between the fin structures 112a and 112b allows the nanosheet channels to attach to both sides of the dielectric wall 119 and form forksheet transistors. The reduced fin-to-fin spacing and fork-like nanosheet transistors enable greater device density (even with greater channel width) and superior area and performance scalability.

Depending on the layouts, the trenches 114c and 114d may have a width corresponding to the first distance D1 or the second distance D2. In one embodiment shown in FIG. 2, the trenches 114c, 114d have a width corresponding to the first distance D1. In some embodiments, a fin structure (not shown) having a width corresponding to W1 may be disposed adjacent to and spaced apart the fin structure 112a by the trench 114d. Likewise, a fin structure (not shown) having a width corresponding to W2 may be disposed adjacent to and spaced apart the fin structure 112c by the trench 114c.

FIGS. 3C-9C and 11C-12C are top-views of the semiconductor device structure 100 of FIG. 2, which may represent a portion of the layout of active fin structures in a SRAM cell 103. For example, a 6T SRAM cell may include two pull-up (PU) transistors, two pass-gate (PG) transistors, and two pull-down (PD) transistors. In one embodiment shown in FIGS. 3C-9C and 11C-12C, the fin structures 112b and 112c can be used to form PU transistors and the fin structure 112a can be used to form PD transistor or PG transistor in the 6T SRAM cell. It should be noted that SRAM is merely an example and should not be considered as a limitation. FIGS. 3A-9A and 11A-12A are cross-sectional side views of various stages of manufacturing the semiconductor device structure 100 taken along line A-A of FIG. 3C, in accordance with some embodiments. FIGS. 3B-9B and 11B-12B are cross-sectional side views of various stages of manufacturing the semiconductor device structure 100 taken along line B-B of FIG. 3C, in accordance with some embodiments.

In FIGS. 4A-4C, a dielectric material 117 is formed in the trenches 114a-114d and over the top surface of the mask structure 110. The dielectric material 117 is deposited so that the fins 112a-c are embedded in the dielectric material 117. The dielectric material 117 may include, but are not limited to, SiOₓ, SiN, SiON, SiCN, SiOCN, AlSiₓO_{y}, Al₂O₃, hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), zirconium oxide (ZrO), zirconium silicon oxide (ZrSiO), titanium oxide (TiO), tantalum oxide (Ta₂O₅), yttrium oxide (Y₂O₃), any suitable low-k materials, any suitable high-k materials, or any combination thereof. The dielectric material 117 may be formed by any suitable process, such as a chemical vapor deposition (CVD), plasma enhanced CVD

(PECVD), flowable CVD (FCVD), atomic layer deposition (ALD), or physical vapor deposition (PVD) process.

In FIGS. 5A-5C, a planarization operation, such as a chemical mechanical polishing (CMP) method, is performed such that the top of the mask structures 110 is exposed. Next, a removal process is performed to remove the dielectric material 117 from the trenches 114a, 114c, and 114d. The removal process may be any suitable etch process, such as dry etch, wet, etch, or a combination thereof. The removal process may be selective etch processes that remove portions of dielectric material 117 but not the mask structure 110, the first sacrificial layers 107, the first semiconductor layers 106, and the second semiconductor layers 108. Because the trenches 114a, 114c, 114d have a larger dimension (i.e., distance D1) in the Y direction compared to that of the trench 114b (FIG. 2), the etchant removes more of the dielectric material 117 in the trenches 114a, 114c, 114d than the dielectric material 117 in the trench 114b. As a result, the dielectric material 117 in the trenches 114a, 114c, 114d are etched at a faster rate than the etch rate of the dielectric material 117 in the trench 114b. The removal process is performed until the dielectric material 117 in the trenches 114a, 114c, 114d are completely etched away. As a result of the removal process, the dielectric material 117 on exposed surfaces of the semiconductor device structure 100 are removed except for the dielectric material 117 filled in the trench 114b, as shown in FIG. 5A. The dielectric material 117 remaining in the trench 114b becomes a dielectric wall 119. The dielectric wall 119 extends all the way down to the well portions 116 of the substrate 101. The dielectric wall 119 forms one dielectric wall that isolates adjacent active fin structures (e.g., fin structures 112b, 112c), which are to be formed as a forksheet transistor. While not shown, the top of the dielectric wall 119 may have a concave profile due to etching effects from the removal process on the dielectric material 117.

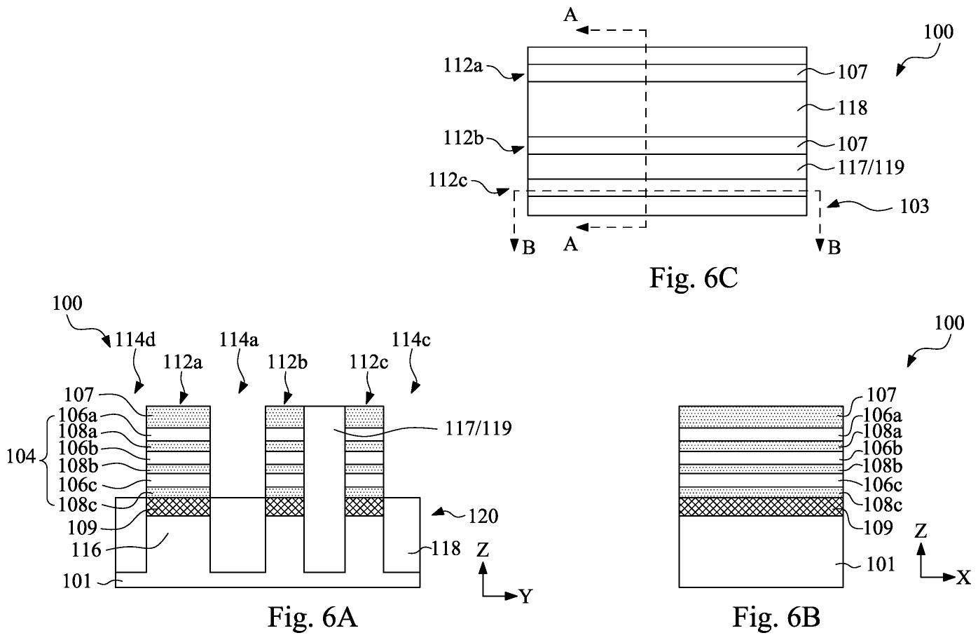

In FIGS. 6A-6C, an insulating material 118 is deposited in the trenches 114a, 114d, 114c to form a shallow-trench isolation (STI) region 120. The insulating material 118 is first formed in the trenches 114a, 114d, 114c and over the dielectric wall 119. Then, a planarization operation, such as a CMP method, is performed such that the top of the first sacrificial layer 107 or dielectric material 117 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), PECVD or FCVD. Then, the insulating material 118 is recessed to form the STI region 120. The insulating material 118 may be recessed using an etch-back process or any suitable process, which can be a dry etching process, a wet etching process, or a combination thereof. The etch-back process may be a selective etch process that removes portions of insulating material 118 but not the dielectric wall 119, the first sacrificial layers 107, the first semiconductor layers 106, and the second semiconductor layers 108. The recess of the insulating material 118 reveals portions of the trenches 114a, 114d, 114c. In some embodiments, the insulating material 118 is recessed such that a top surface of the insulating material 118 is at a level between the bottommost first semiconductor layer 106 (e.g., first semiconductor layer 106c) and the well portion 116. For example, the top surface of the insulating material 118 may be level with or slightly below an interface defined by the second semiconductor layers 108 (e.g., second semiconductor layer 108c) and the second sacrificial layer 109.

In FIGS. 7A-7C, one or more sacrificial gate stacks 142 are formed on the semiconductor device structure 100. FIGS. 7D-9D are cross-sectional side view of various stages of manufacturing the semiconductor device structure 100 taken along line D-D of FIG. 7C, in accordance with some embodiments. The sacrificial gate stacks 142 may each include a sacrificial gate dielectric layer 144, a sacrificial gate electrode layer 146, and a mask structure 148. The sacrificial gate dielectric layer 144 may include one or more layers of dielectric material, such as SiO₂, SiN, a high-k dielectric material, and/or other suitable dielectric material. In some embodiments, the sacrificial gate dielectric layer 144 may be deposited by a CVD process, a sub-atmospheric CVD (SACVD) process, a FCVD process, an ALD process, a PVD process, or other suitable process. The sacrificial gate electrode layer 146 may include polycrystalline silicon (polysilicon). The mask structure 148 may include an oxygen-containing layer 150 and a nitrogen-containing layer 152. The sacrificial gate electrode layer 146 and the mask structure 148 may be formed by various processes such as layer deposition, for example, CVD (including both LPCVD and PECVD), PVD, ALD, thermal oxidation, e-beam evaporation, or other suitable deposition techniques, or combinations thereof.

The sacrificial gate stacks 142 may be formed by first depositing blanket layers of the sacrificial gate dielectric layer 144, the sacrificial gate electrode layer 146, and the mask structure 148, followed by pattern and etch processes. By patterning the sacrificial gate stack 142, the stacks of semiconductor layers 104 of the fin structures 112a, 112b, 112c are partially exposed on opposite sides of the sacrificial gate stack 142. While two sacrificial gate stacks 142 are shown, the number of the sacrificial gate stacks 142 is not limited to two. More than two sacrificial gate stacks 142 may be arranged along the X direction in some embodiments.

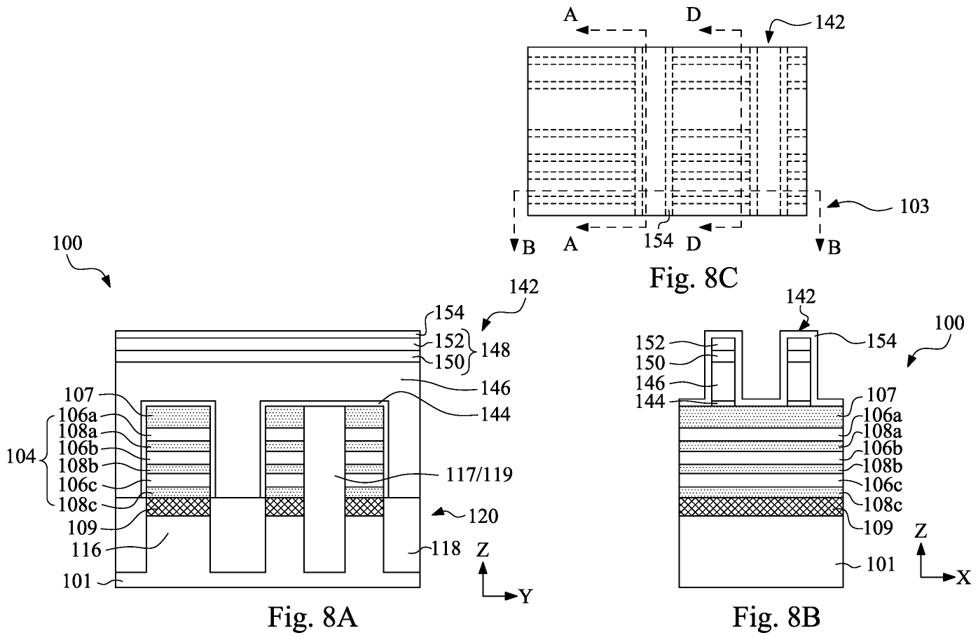

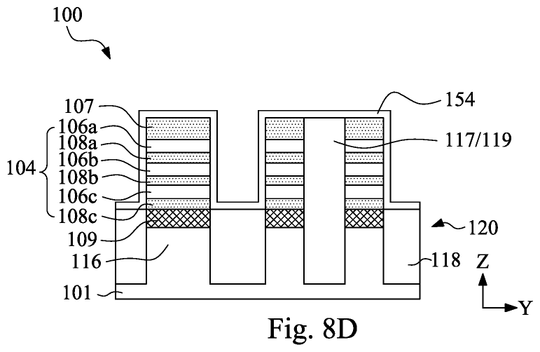

In FIGS. 8A-8D, a gate spacer 154 is formed on the semiconductor device structure 100. The gate spacer 154 may be formed by depositing a blanket layer of a dielectric material for gate spacers on the exposed surfaces of the sacrificial gate stacks 142, the first sacrificial layer 107, and the insulating material 118. The gate spacer 154 may be made of a dielectric material such as silicon oxide, silicon nitride, silicon carbide, silicon oxynitride, SiCN, silicon oxycarbide, silicon oxycarbonitride, and/or combinations thereof. The gate spacer 154 is deposited in a conformal manner (e.g., by an ALD process) so that it is formed to have substantially equal thicknesses. In some embodiments, the gate spacer 154 is deposited to a thickness in a range from about 2 nm to about 10 nm.

In FIGS. 9A-9D, after the blanket layer of the gate spacer 154 is formed, an anisotropic etch process (e.g., RIE) is performed on the gate spacer 154 so that the gate spacer 154 is removed from horizontal surfaces, such as the tops of the fin structures 112a, 112b, 112c, leaving the gate spacers 154 on the vertical surfaces, such as the sidewalls of sacrificial gate stacks 142 and sidewalls of the exposed fin structures 112. In some embodiments, the isotropic etch process may be subsequently performed to remove the gate spacer 154 from the upper portions of the source/drain region of the exposed fin structures 112.

FIGS. 10-1a to 10-7a are cross-sectional side views of a portion 127 of the semiconductor device structure 100 in FIG. 9D showing various stages of manufacturing, in accordance with some embodiments. FIGS. 10-1b to 10-7b are cross-sectional side views of the semiconductor device structure 100 in FIG. 9B showing various stages of manufacturing, in accordance with some embodiments. In FIGS. 10-1a and 10-1b, a portion of the exposed insulating material 118 is removed by an etch process. The etch process may be a dry etch, wet etch, or a combination thereof. The etch process selectively removes the insulating material 118 but does not substantially affect the gate spacer 154, the first sacrificial layer 107, and the dielectric wall 119. The removal of a portion of the insulating material 118 exposes the second sacrificial layer 109. In some embodiments, the etch process is performed so that the top surface of the insulating material 118 is at or slightly below an interface defined by the second sacrificial layer 109 and the well portion 116 formed from the substrate 101.

In FIGS. 10-2a and 10-2b, an etch process is performed to remove the second sacrificial layer 109. The etch process may be a selective etching process that removes the second sacrificial layer 109 without substantially affecting the gate spacers 154, the insulating material 118, and the substrate 101. The etch process may use a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. Due to the higher germanium atomic percentage in the second sacrificial layer 109, the etchant removes the second sacrificial layer 109 at a faster rate than the second semiconductor layer 108. The etch process forms an opening 139 in the region where the second sacrificial layer 109 was removed.

In some embodiments, the etch process is performed so that the etchant removes the second sacrificial layer 109 at the source/drain regions (i.e., regions on either side of the sacrificial gate stacks 142). Once the second sacrificial layers 109 at the source/drain regions are removed, the etch process may continue to etch away the second sacrificial layer 109 under the sacrificial gate stacks 142. The etch process may continue until the entire second sacrificial layer 109 is removed. In such cases, the opening (or air gap) 139 extends continuously along the X-direction from one source/drain region through the region underneath the sacrificial gate stacks 142 and to the adjacent source/drain region, as shown in FIG. 10-2b.

In some embodiments, the etch process is performed so that the etchant removes the second sacrificial layers 109 at the source/drain regions and portions of the second sacrificial layer 109 under the sacrificial gate stacks 142. The etch process may be controlled so that the etchants do not have enough of time to remove the second sacrificial layer 109 underneath the sacrificial gate stacks 142. The removal of the second sacrificial layer 109 forms an opening (or air gap) 139a extending intermittently along the X-direction, as shown in FIG. 10-2b1.

In FIGS. 10-3a and 10-3b, a bottom dielectric material 156 is disposed on the semiconductor device structure 100. The bottom dielectric material 156 may be formed by depositing a blanket layer of a dielectric material for the bottom dielectric material 156 on the exposed surfaces of the gate spacers 154, sacrificial gate stacks 142, the first sacrificial layer 107, and the insulating material 118. The bottom dielectric material 156 also fills in the openings 139 (FIG. 10-2b) or openings 139a (FIG. 10-2b1). In some embodiments, the bottom dielectric material 156 may not completely fill the openings 139, 139a and leave an air gap between the bottom dielectric material 156 and the dielectric wall 119, as shown in FIG. 10-3a1. The bottom dielectric material 156 may be made of a dielectric material such as SiO₂, SiN, SiC, SiCN, SiCON, SiCO, AlO, HfO, other suitable high-k materials (k≥7), and/or combinations thereof. In some embodiments, the bottom dielectric material 156 is a composite with multi-layers of the dielectric material mentioned herein. In some examples, the bottom dielectric material 156 may be a two-layer structure comprising SiO₂ and SiN. In some examples, the bottom dielectric material 156 may be a two-layer structure comprising SiN and SiCN. In some examples, the bottom dielectric material 156 may be a two-layer structure comprising SiN and SiCON. The bottom dielectric material 156 may be deposited in a conformal manner (e.g., by an ALD process). In some embodiments, the bottom dielectric material 156 has a first thickness and the first semiconductor layer 106 has a second thickness less than the first thickness. In some embodiments, the first thickness and the second thickness have a ratio (first thickness:second thickness) in a range of about 1.2:1 to about 3:1, for example about 1.5:1 to about 2:1. In some embodiments, the first thickness is in a range from about 5 nm to about 50 nm. FIG. 10-3b1 illustrates a stage of the semiconductor device structure 100 showing the openings 139a are filled with the bottom dielectric material 156, in accordance with the alternative embodiment of FIG. 10-2b1.

In FIGS. 10-4a and 10-4b, an etch back process is performed on the bottom dielectric material 156 so that the bottom dielectric material 156 is removed from the gate spacers 154, sacrificial gate stacks 142, the first sacrificial layer 107, and the insulating material 118. The bottom dielectric material 156 disposed between the bottommost second semiconductor layer 108 (e.g., second semiconductor layer 108c) and the well portion 116 is not removed due to the coverage of the stacks of semiconductor layers 104 of the fin structures 112. In some embodiments, the bottom dielectric material 156 beneath the gate spacers 154 may also remain. The etch back process may be any suitable isotropic etch process. Upon completion of the etch back process, the sidewall surface of the bottom dielectric material 156 and the sidewall surface of the stack of semiconductor layers 104 (or the gate spacer 154) are flushed. In some embodiments, the remaining bottom dielectric material 156 has a first sidewall exposed to air and a second sidewall opposing the first sidewall and in contact with the dielectric wall 119. In some embodiments where an air gap was previously formed between the bottom dielectric material 156 and the dielectric wall 119 (i.e., the embodiment shown in FIG. 10-3a1), both the first and second sidewalls of the remaining bottom dielectric material 156 may be exposed to air.

In FIGS. 10-5a and 10-5b, exposed portions of the stack of semiconductor layers 104 and the gate spacers 154 at the source/drain regions not covered by the sacrificial gate stacks 142 and the gate spacers 154 are selectively recessed by one or more suitable etch processes, such as dry etch, wet etch, or a combination thereof. In some embodiments, portions of the bottom dielectric material 156 are removed. Since the etchant may have poor reaction rate at or near the corner of the dielectric wall 119, the remaining bottom dielectric material 156 may have an angled top surface 156t having a slope gradually decreased in height from the dielectric wall 119 towards a direction away from the dielectric wall 119. In some embodiments, the bottom dielectric material 156 is etched so that the bottom dielectric material 156 beneath the sacrificial gate stacks 142 has a first height and the bottom dielectric material 156 at the source/drain regions has a second height lower than the first height by a distance D3. In some cases, the distance D3 is in a range between about 0.1 nm to about 1.5 nm. In any case, the remaining bottom dielectric material 156 covers portions of the well portions 116 and the dielectric wall 119, as shown in FIG. 10-5a.

FIG. 10-5b1 illustrates a stage of the semiconductor device structure 100 after removal of portions of the stack of semiconductor layers 104, in accordance with the alternative embodiment of FIG. 10-2b1. In this embodiment, the one or more etch processes are performed so that the second sacrificial layer 109 beneath the sacrificial gate stacks 142 has a first height and the bottom dielectric material 156 at the source/drain regions has a second height lower than the first height by a distance D4. In some cases, the distance D4 is in a range between about 0.1 nm to about 1.5 nm.

In some embodiments, which can be combined with one or more embodiments of the present disclosure, the one or more etch processes are performed so that the exposed bottom dielectric material 156 at either source or drain regions are further removed. For example, a mask (e.g., a patterned resist layer) may be provided at the drain region while the one or more etch processes are performed on the source region. FIGS. 10-5a1 and 10-5b2 illustrate an embodiment where the exposed bottom dielectric material 156 at the source region is removed. In such cases, the well portion 116 is exposed as a result of removal of the bottom dielectric material 156. In some cases, the top surface of the exposed well portion 116 may be slightly recessed. FIG. 10-5b3 illustrates a stage of the semiconductor device structure 100 after removal of portions of the stack of semiconductor layers 104 and the bottom dielectric material 156 at the source/drain regions, in accordance with the alternative embodiment of FIG. 10-2b1.

In some embodiments, which can be combined with one or more embodiments of the present disclosure, the one or more etch processes are performed so that the exposed bottom dielectric material 156 at the NMOS region or PMOS region of either source or drain region are further removed, as shown in FIG. 10-5a2.

In FIGS. 10-6a and 10-6b, edge portions of the first sacrificial layers 107 and each second semiconductor layer 108 (e.g., 108a, 108b, 108c) of the stack of semiconductor layers 104 are removed horizontally along the X direction. The removal of the edge portions of the first sacrificial layers 107 and the second semiconductor layers 108 forms cavities. In some embodiments, the portions of the first sacrificial layers 107 and the second semiconductor layers 108 are removed by a selective wet etching process. In cases where the first sacrificial layers 107 and the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. The wet etchant may not affect, or have limited impact, on the bottom dielectric material 156 due to its higher atomic percentage of germanium. FIG. 10-6b1 illustrates a stage of the semiconductor device structure 100 after removal of edge portions of the first sacrificial layers 107 and the second semiconductor layers 108, in accordance with the alternative embodiment of FIG. 10-2b1.

After removing edge portions of the first sacrificial layers 107 and each second semiconductor layers 108, a dielectric layer is deposited in the cavities to form dielectric spacers 151. The dielectric spacers 151 may be made of a low-K dielectric material, such as SiON, SiCN, SiOC, SiOCN, or SiN. The dielectric spacers 151 may be formed by first forming a conformal dielectric layer using a conformal deposition process, such as ALD, followed by an anisotropic etching to remove portions of the conformal dielectric layer other than the dielectric spacers 151. The dielectric spacers 151 are protected by the first semiconductor layers 106 during the anisotropic etching process. The remaining first sacrificial layers 107 and second semiconductor layers 108 (e.g., 108a, 108b, 108c) are capped between the dielectric spacers 151 along the X direction.

In FIGS. 10-7a and 10-7b, epitaxial S/D features 160a, 160b are grown from the first semiconductor layers 106 and formed on the bottom dielectric material 156. The epitaxial S/D features 160a, 160b may be the S/D regions. For example, one of a pair of epitaxial S/D features 160a located on one side of the stack of semiconductor layers 104 can be a source region, and the other of the pair of epitaxial S/D features 160b located on the other side of the stack of semiconductor layers 104 can be a drain region. A pair of epitaxial S/D features 160 includes an epitaxial source feature 160a and a drain epitaxial feature 160b connected by the nanosheet channels (i.e., the first semiconductor layers 106). Source/drain region(s) may refer to a source or a drain, individually or collectively dependent upon the context. In this disclosure, a source and a drain are interchangeably used, and the structures thereof are substantially the same.

For n-channel FETs, for example epitaxial S/D features 160b, the epitaxial S/D features 160b may include one or more layers of Si, SiP, SiC, SiCP, or a group III-V material (InP, GaAs, AlAs, InAs, InAlAs, InGaAs). In some embodiments, the epitaxial S/D features 160b may be doped with n-type dopants, such as phosphorus (P), arsenic (As), etc, for n-type devices. For p-channel FETs, for example epitaxial S/D features 160a, the epitaxial S/D features 160a may include one or more layers of Si, SiGe, SiGeB, Ge, or a group III-V material (InSb, GaSb, InGaSb). In some embodiments, the epitaxial S/D features 160a may be doped with p-type dopants, such as boron (B). The epitaxial S/D features 160a, 160b may grow both vertically and horizontally to form facets, which may correspond to crystalline planes of the material used for the first semiconductor layer 106. The epitaxial S/D features 160a, 160b may be formed by an epitaxial growth method using CVD, ALD or MBE.

In some embodiments, which can be combined with one or more embodiments of the present disclosure, the epitaxial S/D features 160a, 160b are grown from semiconductor surfaces (e.g., the first semiconductor layers 106) and may not form on the bottom dielectric material 156, which has a dielectric surface. Therefore, an air gap 159 may be formed between the epitaxial S/D features 160a, 160b and the bottom dielectric material 156, as shown in FIGS. 10-7a1 and 10-7b2. The air gap 159 may have a height in a range of about 2 nm to about 15 nm. In some embodiments, the epitaxial S/D features 160a, 160b at the drain region may be electrically connected to a drain node. In some embodiments, the epitaxial S/D features 160b at the source region may be electrically connected to a negative voltage (VSS) contact, and the epitaxial S/D features 160a at the source region may be electrically connected to a positive voltage (VDD) contact. FIG. 10-7b3 illustrates a stage of the semiconductor device structure 100 showing an air gap 159 formed between the epitaxial S/D features 160a, 160b and the bottom dielectric material 156, in accordance with the alternative embodiment of FIG. 10-2b1.

In some embodiments, which can be combined with one or more embodiments of the present disclosure, the epitaxial S/D features 160a, 160b may be formed (through time control, for example) such that the air gap 159 is only provided at the PMOS region. That is, the epitaxial S/D feature 160a at the PMOS region is separated from the bottom dielectric material 156 by the air gap 159, while the epitaxial S/D feature 160b at the NMOS region is contact with the bottom dielectric material 156, as shown in FIG. 10-7a2. In such cases, the epitaxial S/D features 160a at the PMOS region and the epitaxial S/D features 160b at the NMOS region may both electrically connect to a contact node (e.g., VDD or VSS contact).

In FIGS. 11A-11D, a contact etch stop layer (CESL) 162 is formed on exposed surfaces of the epitaxial S/D features 160a, 160b, the gate spacers 154, and the nitrogen-containing layer 152 of the mask structure 148. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof. The CESL 162 may be formed by CVD, PECVD, ALD, or any suitable deposition technique. In some embodiments, the CESL 162 is a conformal layer formed by the ALD process. Next, an interlayer dielectric (ILD) layer 164 is formed on the CESL 162. The materials for the ILD layer 164 may include an oxide formed from tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 164 may be deposited by a PECVD process or other suitable deposition technique. In some embodiments, after formation of the ILD layer 164, the semiconductor device structure 100 may be subject to a thermal process to anneal the ILD layer 164.

In some embodiments, which can be combined with one or more embodiments of the present disclosure, the CESL 162 and the bottom dielectric material 156 may be formed of the same material. In some embodiments, which can be combined with one or more embodiments of the present disclosure, the CESL 162 and the bottom dielectric material 156 may be formed of a material that is chemically different from one another. FIG. 11D-1 illustrates an embodiment where the CESL 162a and the bottom dielectric material 156 include the same material. In some embodiments, the epitaxial S/D features 160a at the PMOS region and the epitaxial S/D features 160b at the NMOS region may both electrically connect to a contact node (e.g., VDD or VSS contact).

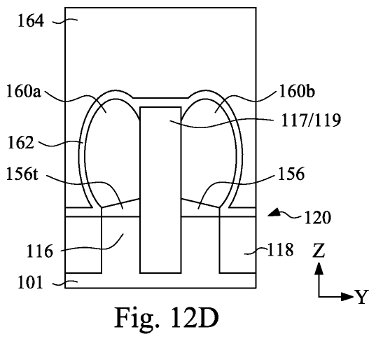

In FIGS. 12A-12D, a planarization process, such as a CMP process, is performed until the tops of the sacrificial gate electrode layer 146 and the gate spacers 154 are exposed. The planarization process removes portions of the ILD layer 164 and the CESL 162 disposed on the sacrificial gate stacks 142. In some embodiments, the ILD layer 164 may be recessed to a level at the top of the sacrificial gate electrode layer 146. In such cases, a nitrogen-containing layer (not shown), such as a SiCN layer, may be formed on the recessed ILD layer 164 to protect the ILD layer 164 during subsequent etch processes.

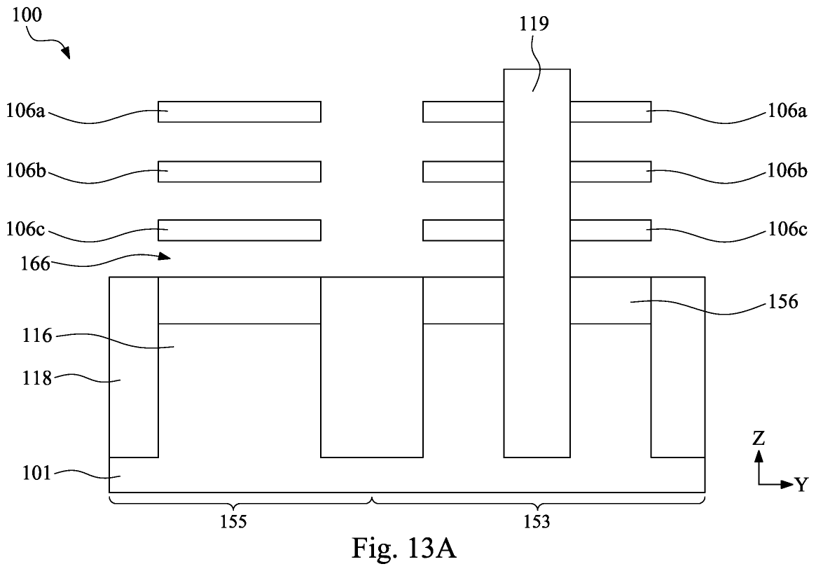

FIGS. 13A-16A are cross-sectional views of various stages of manufacturing the semiconductor device structure 100 of FIG. 12A, in accordance with some embodiments. In FIG. 13A, the sacrificial gate electrode layer 146 and the sacrificial gate dielectric layer 144 (FIGS. 12A-12C) are removed, exposing portions of the first sacrificial layers 107 and the stacks of semiconductor layers 104 (e.g., topmost first semiconductor layer 106a). The sacrificial gate electrode layer 146 may be first removed by any suitable etch process, such as dry etch, wet etch, or a combination thereof, followed by the removal of the sacrificial gate dielectric layer 144, which may be performed by any suitable process, such as dry etch, wet etch, or a combination thereof. The etch process may be one or more selective etch processes that remove the sacrificial gate electrode layer 146 and the sacrificial gate dielectric layer 144 but not the gate spacers 154, the CESL 162, and the ILD layer 164.

Next, the first sacrificial layers 107 and the second semiconductor layers 108 are removed. The removal process exposes portions of the dielectric wall 119, the first semiconductor layers 106 (106a-c), and a portion of the insulating material 118. The removal process may be any suitable processes, such as dry etch, wet etch, or a combination thereof. The removal process may be a selective etch process that removes the first sacrificial layers 107 and the second semiconductor layers 108 but not the first semiconductor layers 106, the gate spacers 154, the dielectric walls 119, and the CESL 162. In cases where the first sacrificial layers 107 and the second semiconductor layers 108 are made of SiGe, and the first semiconductor layers 106 are made of silicon, a selective wet etching including an ammonia and hydrogen peroxide mixtures (APM) may be used. As a result of the etch process, openings 166 are formed, leaving the first semiconductor layers 106a-c (from fin structures 112b and 112c) protruded from opposing sides of the dielectric wall 119. The portions of the first semiconductor layers 106 not covered by the dielectric spacers 151 (not shown) are exposed in the openings 166. Specifically, each of the first semiconductor layers 106a, 106b, 106c has a first end in contact with the dielectric wall 119 and a second end (i.e., distal end) extending away from the first end. The first semiconductor layers 106a-c (from fin structure 112a) are disposed adjacent the first semiconductor layers 106a-c (from fin structures 112b and 112c), as shown in FIG. 13A. Having the first end of the first semiconductor layers 106a, 106b, 106c directly connected to a portion of the dielectric wall 119 saves the space for subsequent metal gate and increases the overall pattern density. The first semiconductor layers 106a-c from the fin structures 112b and 112c serve as channel regions for forksheet transistors to be formed at region 153. The first semiconductor layers 106a-c from the fin structure 112a serve as channel regions for nanosheet transistors to be formed at region 155.

In some embodiments, the first semiconductor layers 106a-c at the region 153 on one side of the dielectric wall 119 may be designated as a P-type FET or N-type FET of the forksheet transistor, and the first semiconductor layers 106a-c at the region 153 on the other side of the dielectric wall 119 may be designated as an N-type FET or P-type FET of the forksheet transistor. In some embodiments, the first semiconductor layers 106a-c at the region 155 adjacent the region 153 may be designated as a P-type FET or N-type FET of the nanosheet transistor. In one exemplary embodiment shown in FIG. 13A, the first semiconductor layers 106a-c at the region 153 on the right-hand side of the dielectric wall 119 is designated as a N-type FET of the forksheet transistor, the first semiconductor layers 106a-c at the region 153 on the left-hand side of the dielectric wall 119 is designated as a P-type FET of the forksheet transistor, and the first semiconductor layers 106a-c at the region 155 adjacent the region 153 is designated as a P-type FET of the nanosheet transistor. Alternatively, the first semiconductor layers 106a-c at the region 155 adjacent the region 153 can be designated as N-type FET of the nanosheet transistor. It should be noted that while the region 153 is shown as immediately adjacent to the region 155, the regions 153 and 155 may be separated from each other by other devices, transistors, or features.

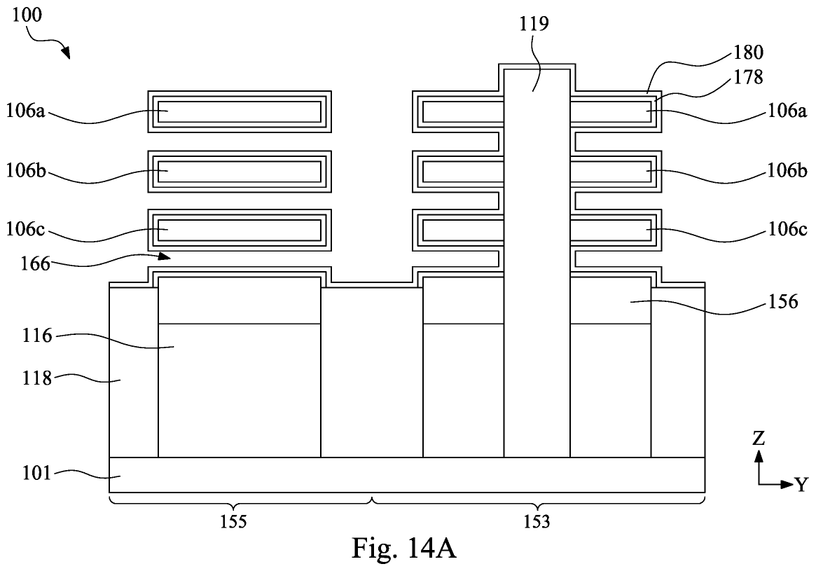

In FIG. 14A, an interfacial layer (IL) 178 is formed to surround at least three surfaces of the first semiconductor layers 106 (e.g., first semiconductor layers 106a, 106b, 106c). The IL 178 may also form on the exposed surfaces of the bottom dielectric material 156. In some embodiments, the IL 178 may form on the first semiconductor layers 106 but not on the exposed insulating material 118. The IL 178 may include or be made of an oxygen-containing material or a silicon-containing material, such as silicon oxide, silicon oxynitride, oxynitride, hafnium silicate, etc. The IL 178 may be formed by CVD, ALD or any suitable conformal deposition technique. In one embodiment, the IL 178 is formed using ALD. The thickness of the IL 178 is chosen based on device performance considerations. In some embodiments, the IL 178 has a thickness ranging from about 0.5 nm to about 2 nm.

Next, a high-k (HK) dielectric layer 180 is formed on the exposed surfaces of the semiconductor device structure 100. In some embodiments, the HK dielectric layer 180 is formed on the IL 178, a portion of the insulating material 118, and on the exposed surfaces of the dielectric wall 119, as shown in FIG. 16. The HK dielectric layer 180 may include or be made of the same material as the first and second high-k dielectric layers 140, 143. The HK dielectric layer 180 may be a conformal layer formed by a conformal process, such as an ALD process or a CVD process. The HK dielectric layer 180 may have a thickness of about 0.5 nm to about 3 nm, which may vary depending on the application.

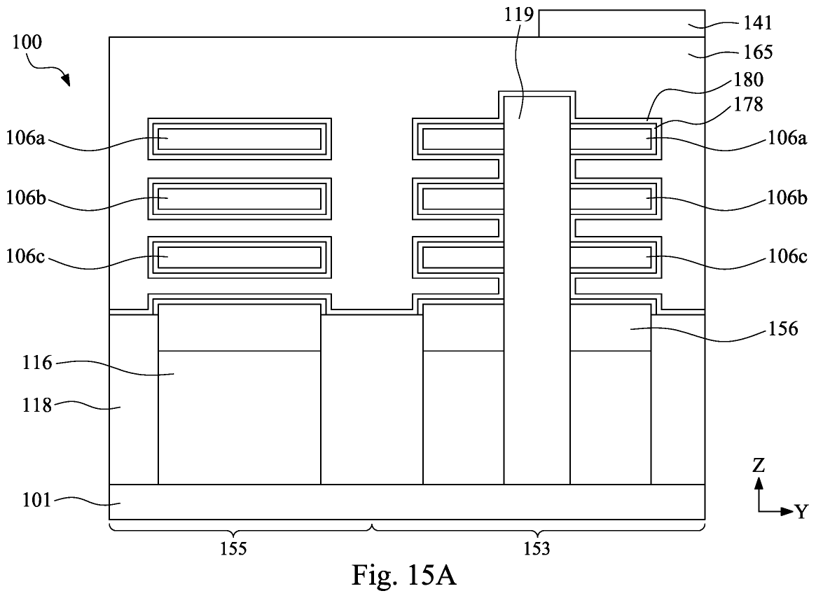

In FIG. 15A, after formation of the IL 178 and the HK dielectric layer 180, a first gate electrode layer 165 is formed in the openings 166 (FIG. 14A). The first gate electrode layer 165 is formed on the HK dielectric layer 180 to surround a portion of each first semiconductor layer 106a, 106b, 106c and on the insulating material 118. The first gate electrode layer 165 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The first gate electrode layer 165 may be deposited so that at least the forksheet transistors and the nanosheet transistors to be formed at the regions 153, 155 are submerged in the first gate electrode layer 165. The first gate electrode layer 165 may be formed to a predetermined height above the dielectric wall 119, as shown in FIG. 15A. In some embodiments, the first gate electrode layer 165 is deposited to a height over a top surface of the HK dielectric layer 180 over the dielectric wall 119. In some embodiments, the first gate electrode layer 165 may be formed using multiple layers, each layer deposited sequentially adjacent to each other using a highly conformal deposition process such as ALD. Other deposition technique such as PVD, CVD, or electro-plating may also be used. While not shown, the first gate electrode layer 165 may include a capping layer, a barrier layer, an n-metal work function layer, a p-metal work function layer, and a fill material. The capping layer and the barrier layer may be metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be formed of a material different from the capping layer. The n-metal work function layer may be formed from a metallic material such as W, Cu, AlCu, TiAlC, TiAlN, Ti, TiN, Ta, TaN, Co, Ni, Ag, Al, TaAl, TaAlC, TaC, TaCN, TaSiN, Mn, Zr, other suitable n-type work function materials, or combinations thereof. The p-metal work function layer may be formed from a metallic material such as W, Al, Cu, TiN, Ti, TiAlN, Ta, TaN, Co, Ni, TaC, TaCN, TaSiN, TaSi₂, NiSi₂, Mn, Zr, ZrSi₂, TaN, Ru, AlCu, Mo, MoSi₂, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

Next, a patterned resist layer 141 is formed on the exposed surfaces of the semiconductor device structure 100. The patterned resist layer 141 may be first formed to cover N-type FETs, such as N-type FETs of the forksheet transistors at the region 153, while the P-type FETs, such as P-type FETs of the forksheet transistors at the region 153 and the P-type FETs of the nanosheet transistors at the region 155, are left uncovered. The patterned resist layer 141 may be formed by first forming a blanket layer on the semiconductor device structure 100, followed by patterning and etching processes to remove portions of the blanket layer at selected regions to form the patterned resist layer 141. The patterned resist layer 141 may be any suitable masking material, such as a photoresist layer, a BARC (bottom anti-reflective coating) layer, a SOG (spin-on-glass) layer, or a SOC (spin-on-carbon) layer, and may be deposited by spin coating or any suitable deposition technique.

In FIG. 16A, portions of the first gate electrode layer 165 at the region 153 not covered by the patterned resist layer 141 are removed and a second gate electrode layer 163 is formed in the region where the first gate electrode layer 165 was removed. The patterned resist layer 141 protects portions of first gate electrode layer 165 on one side of the dielectric wall 119 at the region 153 so that the first gate electrode layer 165 on the other side of the dielectric wall 119 and the first gate electrode layer 165 at the region 155 are removed. The first gate electrode layer 165 may be removed using any suitable processes, such as dry etch, wet etch, or a combination thereof. The removal process may be a selective etch process that removes the first gate electrode layer 165 but not the HK dielectric layer 180.

Next, the second gate electrode layer 163 is formed on the exposed HK dielectric layer 180 and in the region where the first gate electrode layer 165 was removed. The second gate electrode layer 163 may be deposited so that at least the nanosheet transistors at the regions 155 are submerged in the second gate electrode layer 163. The second gate electrode layer 163 surrounds a portion of each first semiconductor layer 106 at the region 155. In some embodiments, the second gate electrode layer 163 is deposited so that the top surface of the second gate electrode layer 163 is substantially co-planar with the first gate electrode layer 165. The second gate electrode layer 163 may include the same material as the first gate electrode layer 165. In some embodiments, the second gate electrode layer 163 is chemically different than the first gate electrode layer 165. Likewise, the second gate electrode layer 163 may be formed using multiple layers, each layer deposited sequentially adjacent to each other using a highly conformal deposition process such as ALD. The second gate electrode layer 163 may also include a capping layer, a barrier layer, an n-metal work function layer, a p-metal work function layer, such as those used for the first gate electrode layer 165. Each layer in the first and second gate electrode layers 165, 163 may be chosen depending on the threshold voltage and application of the NMOS or PMOS devices needed for regions 153, 155.

After the formation of the second gate electrode layer 163, the resist layer 141 is removed using any suitable removal process, such as ashing, dry etch, wet etch, or a combination thereof. A planarization operation, such as a CMP method and/or an etch-back method, may be performed so that the top surfaces of the first and second gate electrode layers 165, 163 are substantially co-planar. FIG. 16B is a cross-sectional side view of the semiconductor device structure 100 taken along line B-B of FIG. 12C, showing a stage after the formation of the first and second gate electrode layers 165, 163, in accordance with some embodiments.

As a result of the formation of the first and second gate electrode layers 165, 163, a forksheet transistor 182 and a nanosheet transistor 184 are formed at the region 153 and the region 155, respectively. In one exemplary embodiment, the forksheet transistor 182 includes a NMOS device 182-1 extending outwardly from one side of the dielectric wall 119, and a PMOS device 182-2 extending outwardly form another side of the dielectric wall 119. The nanosheet transistor 184 includes a PMOS device. The forksheet transistor 182 includes a bottom dielectric material 156 extending outwardly from both sides of the dielectric wall 119. In some embodiments, the first semiconductor layers 160a-c of the nanosheet transistor 184 have a channel width W3 substantially corresponding to the width W1 (FIG. 2) of the fin structure 112a, and the first semiconductor layers 106a-c of the forksheet transistor 182 extending from one side (or both sides) of the dielectric wall 119 has a channel width W4 corresponding to the width W2 (FIG. 2). In various embodiments, the channel width W3 is greater than the channel width W4. In some embodiments, the channel width W3 may be in a range of about 5 nm to about 120 nm. The nanosheet transistor 184 provides higher speed and current than the forksheet transistor 182 due to greater channel width W3. The nanosheet transistors 184 therefore are more suitable for high-speed applications, such as a NAND device or high-performance computing (HPC). The devices with a narrower channel, such as the device fabricated from the fin structures 112b, 112c, may be more suitable for low-power and low-leakage applications, such as an inverter device or system-on-chip (SOC).

FIG. 16A-1 illustrates a cross-sectional view of the semiconductor device structure 100 in accordance with some embodiments. The embodiment in FIG. 16A-1 is substantially identical to the embodiment of FIG. 16A except that a nanosheet transistor 186 is further formed at the region 157 adjacent to the region 155 on which the nanosheet transistor 184 is formed. The nanosheet transistor 186 may be a transistor having a conductivity opposite to the nanosheet transistor 184. In one exemplary embodiment, the forksheet transistor 182 includes a NMOS device 182-1 extending outwardly from one side of the dielectric wall 119, and a PMOS device 182-2 extending outwardly form another side of the dielectric wall 119. The nanosheet transistor 184 includes a PMOS device. In another exemplary embodiment, the forksheet transistor 182 includes a PMOS device extending outwardly from one side of the dielectric wall 119, and a NMOS device extending outwardly form another side of the dielectric wall 119. The nanosheet transistor 186 includes a NMOS device. In various embodiments, the nanosheet transistor 186 has a channel width W3-1 that is greater than the channel width W4. In some embodiments, the channel width W3-1 may be equal to the channel width W3 of the nanosheet transistor 184. The nanosheet transistors 184 and 186 provide higher speed and current than the forksheet transistor 182 due to greater channel widths W3 and W3-1.

FIGS. 17-1a to 22-1a are cross-sectional side views of various stages of manufacturing a semiconductor device structure 200 taken along a plane in the source/drain region, in accordance with some alternative embodiments. FIGS. 17-1b to 22-1b are cross-sectional side views of various stages of manufacturing the semiconductor device structure 200 taken along a plane in the fin structure, in accordance with some alternative embodiments. The embodiments shown in FIGS. 17-1a and 17-1b to 22-1a and 22-1b are substantially identical to the embodiments of FIGS. 1-16B except that the bottom dielectric material is not formed until after portions of the stack of semiconductor layers 104 and the gate spacers 154 at the source/drain regions are selectively recessed.

In FIGS. 17-1a and 17-1b, the sacrificial gate stacks 142 are formed on the stack of semiconductor layers 104 and gate spacers 154 are formed on sidewalls of the sacrificial gate stacks 142. Unlike the embodiment shown in 10-4a and 10-4b, the bottommost second semiconductor layer (e.g., second semiconductor layer 108c) is in direct contact with the well portion 116 without a bottom dielectric material 156 disposed therebetween.

In FIGS. 18-1a and 18-1b, exposed portions of the stack of semiconductor layers 104 and the gate spacers 154 at the source/drain regions not covered by the sacrificial gate stacks 142 and the gate spacers 154 are selectively recessed by one or more suitable etch processes. The removal of the portions of the stack of semiconductor layers 104 and the gate spacers 154 forms a recess 239. In some embodiments, a top portion of the fin structures (e.g., well portion 116) is also removed. Since the etchant may have poor reaction rate at or near the corner of the dielectric wall 119, the remaining fin structures may have an angled top surface 116t having a slope gradually decreased in height from the dielectric wall 119 towards a direction away from the dielectric wall 119.

In FIGS. 19-1a and 19-1b, a bottom dielectric material 256, such as the bottom dielectric material 156, is disposed in the recess 239. The bottom dielectric material 256 may be formed by depositing a blanket layer of a dielectric material for the bottom dielectric material 256 on the exposed surfaces of the gate spacers 154, sacrificial gate stacks 142, the first sacrificial layer 107, the stack of semiconductor layers 104, and the insulating material 118. The bottom dielectric material 156 also fills in the recess 239. Next, a pre-treatment, such as a nitrogen-based plasma treatment, is performed on the bottom dielectric material 256. An etch back process, such as an isotropic etch process, is then performed to remove the treated bottom dielectric material 256 from the gate spacers 154, sacrificial gate stacks 142, the first sacrificial layer 107, the stack of semiconductor layers 104, and the insulating material 118. Due to physical limitation, the treated bottom dielectric material 256 in the recess 239 is etched at a reaction rate slower than that of the treated bottom dielectric material 256 on the gate spacers 154, sacrificial gate stacks 142, the first sacrificial layer 107, the stack of semiconductor layers 104, and the insulating material 118. As a result, the treated bottom dielectric material 256 remains in the recess 239 after the etch back process.

In FIGS. 20-1a and 20-1b, edge portions of the first sacrificial layers 107 and each second semiconductor layer 108 (e.g., 108a, 108b, 108c) of the stack of semiconductor layers 104 are removed, and dielectric spacers 151 is formed in the cavities formed as a result of removal of the edge portions of the first sacrificial layers 107 and each second semiconductor layer 108.

In FIGS. 21-1a and 21-1b, epitaxial S/D features 160a, 160b are grown from the first semiconductor layers 106 and formed on the bottom dielectric material 256 in a similar fashion as discussed above with respect to FIGS. 10-7a and 10-7b. In some embodiments, the epitaxial S/D features 160a, 160b at the drain region may be electrically connected to a drain node. In some embodiments, the epitaxial S/D features 160b at the source region may be electrically connected to a VSS contact, and the epitaxial S/D features 160a at the source region may be electrically connected to a VDD contact.

FIGS. 21-1a1 and 21-1b1 illustrate an alternative embodiment where an air gap 259 is formed between the epitaxial S/D features 160a, 160b and the bottom dielectric material 256, in a similar fashion as discussed above with respect to FIGS. 10-7a1 and 10-7b2. Likewise, the air gap 259 may have a height in a range of about 2 nm to about 15 nm. In some embodiments, the epitaxial S/D features 160a, 160b at the drain region may be electrically connected to a drain node. In some embodiments, which can be combined with one or more embodiments of the present disclosure, the epitaxial S/D features 160a, 160b may be formed such that the air gap 259 is only provided at the PMOS region. That is, the epitaxial S/D feature 160a at the PMOS region is separated from the bottom dielectric material 156 by the air gap 259, while the epitaxial S/D feature 160b at the NMOS region is contact with the bottom dielectric material 156, as shown in FIG. 21-1a2. In such cases, the epitaxial S/D features 160a at the PMOS region and the epitaxial S/D features 160b at the NMOS region may both electrically connect to a contact node (e.g., VDD or VSS contact).

In FIGS. 22-1a and 22-1b, a contact etch stop layer (CESL) 162 and an ILD layer 164 is sequentially formed on exposed surfaces of the epitaxial S/D features 160a, 160b, the gate spacers 154, and the nitrogen-containing layer 152 of the mask structure 148, in a similar fashion as discussed above with respect to FIGS. 11A-11D. The semiconductor device structure 200 is then subjected to various manufacturing processes as discussed above with respect to FIGS. 13A-16A. FIG. 22B is a cross-sectional side view of the semiconductor device structure 200 taken along plane in the fin structure (fin structure 112c of FIG. 3C), showing a stage after the formation of the first and second gate electrode layers 165, 163, in accordance with some embodiments.

It is understood that the semiconductor device structures 100, 200 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 by flipping over the semiconductor device structure 100, removing the substrate 101, and selectively connecting source or drain feature/terminal of the epitaxial S/D features 160 to a backside power rail (e.g., positive voltage VDD or negative voltage VSS) through the backside contacts. Depending on the application, the source or drain feature/terminal of the epitaxial S/D features 160 and the first and second gate electrode layers 165, 163 may be connected to a frontside power source.

Various embodiments of the present disclosure provide an improved semiconductor device structures having a forksheet transistor and a nanosheet transistor. Particularly, a bottom dielectric material is formed in the forksheet transistor and interacted with the dielectric wall. Epitaxial S/D features is formed above the bottom dielectric material with or without an air gap disposed therebetween. The bottom dielectric material isolate source/drain features (or epitaxial S/D feature at drain regions) to the planar channel (e.g., well portion formed from a substrate, thereby preventing or minimizing leakage through the planar channel while reducing overall capacitance at both metal gate-source/drain regions and source/drain regions and well portion of the bulk silicon.

An embodiment is a semiconductor device structure. The semiconductor device structure includes a dielectric wall disposed over a substrate, a plurality of first semiconductor layers vertically stacked and extended outwardly from a first side of the dielectric wall, a plurality of second semiconductor layers vertically stacked and extended outwardly from a second side of the dielectric wall, a first epitaxial source/drain (S/D) feature disposed on the first side of the dielectric wall, a second epitaxial S/D feature disposed on the second side of the dielectric wall, a first bottom dielectric layer extended outwardly from the first side of the dielectric wall, and a second bottom dielectric layer extended outwardly from the second side of the dielectric wall.

Another embodiment is a semiconductor device structure. The semiconductor device structure includes a dielectric wall disposed between and in contact with a first fin structure and a second fin structure, a first source/drain (S/D) feature disposed on a first side of the dielectric wall, a second S/D feature disposed on a second side of the dielectric wall, a plurality of first semiconductor layers vertically stacked and extended outwardly from the first side of the dielectric wall, a plurality of second semiconductor layers vertically stacked and extended outwardly from the second side of the dielectric wall, a first gate electrode layer surrounding at least three surfaces of each of the first semiconductor layers, the first gate electrode layer having a first conductivity type, a second gate electrode layer surrounding at least three surfaces of each of the second semiconductor layers, the second gate electrode layer having a second conductivity type opposite the first conductivity type, a first bottom dielectric layer disposed between the first fin structure and the first S/D feature, and a second bottom dielectric layer disposed between the second fin structure and the second S/D feature.

A further embodiment is a method. The method includes forming first and second fin structures from a substrate, wherein the first fin structure includes a first plurality of semiconductor layers over a first sacrificial layer, and the second fin structure includes a second plurality of semiconductor layers over a second sacrificial layer, and wherein each of the first and second plurality of semiconductor layers comprises first semiconductor layers and second semiconductor layers, forming a dielectric wall between the first fin structure and the second fin structure, forming an insulating material between the second and third fin structures, forming a sacrificial gate stack over a portion of the first and second fin structure, selectively removing the first and second sacrificial layers to form an opening, filling the opening with a bottom dielectric material, forming a source/drain features over the bottom dielectric material, selectively removing the second semiconductor layers of the first and second plurality of semiconductor layers, forming an interfacial layer (IL) to surround at least three surfaces of the first semiconductor layers of the first and second fin structures and exposed surfaces of the bottom dielectric material, and forming a gate electrode layer over the IL.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a dielectric wall disposed over a substrate;
a plurality of first semiconductor layers vertically stacked and extended outwardly from a first side of the dielectric wall;
a plurality of second semiconductor layers vertically stacked and extended outwardly from a second side of the dielectric wall;
a first epitaxial source/drain (S/D) feature disposed on the first side of the dielectric wall;
a second epitaxial S/D feature disposed on the second side of the dielectric wall;
a first bottom dielectric layer extended outwardly from the first side of the dielectric wall; and
a second bottom dielectric layer extended outwardly from the second side of the dielectric wall.

2. The semiconductor device structure of claim 1, wherein the first bottom dielectric layer is disposed below the first epitaxial S/D feature, and the second bottom dielectric layer is disposed below the second epitaxial S/D feature.

3. The semiconductor device structure of claim 2, wherein the second bottom dielectric layer is separated from the second epitaxial S/D feature by a first air gap.

4. The semiconductor device structure of claim 3, wherein the first bottom dielectric layer is in contact with the first epitaxial S/D feature.

5. The semiconductor device structure of claim 3, wherein the first bottom dielectric layer is separated from the first epitaxial S/D feature by a second air gap.

6. The semiconductor device structure of claim 1, further comprising:
a first gate electrode layer surrounding at least three surfaces of each of the first semiconductor layers, the first gate electrode layer having a first conductivity type; and
a second gate electrode layer surrounding at least three surfaces of each of the second semiconductor layers, the second gate electrode layer having a second conductivity type opposite the first conductivity type.

7. The semiconductor device structure of claim 6, wherein the first bottom dielectric layer is disposed below the first gate electrode layer, and the second bottom dielectric layer is disposed below the second gate electrode layer.

8. The semiconductor device structure of claim 6, further comprising:
an interfacial layer (IL) surrounding at least three surfaces of each of the first and second semiconductor layers; and
a high-k dielectric layer disposed on the IL.

9. The semiconductor device structure of claim 8, wherein the IL is in contact with the high-k dielectric layer, the first bottom dielectric layer, and second bottom dielectric layer.

10. The semiconductor device structure of claim 1, wherein the first and second dielectric layers have a first thickness, and each of the first and second semiconductor layers has a second thickness less than the first thickness.

11. The semiconductor device structure of claim 1, further comprising:
an interlayer dielectric (ILD) layer disposed over the first and second epitaxial S/D features; and
a contact etch stop layer (CESL) disposed between and in contact with the ILD and the first and second epitaxial S/D features.

12. The semiconductor device structure of claim 11, wherein the CESL comprises a material chemically different than that of the first and second bottom dielectric layers.

13. A semiconductor device structure, comprising:
a dielectric wall disposed between and in contact with a first fin structure and a second fin structure;
a first source/drain (S/D) feature disposed on a first side of the dielectric wall;
a second S/D feature disposed on a second side of the dielectric wall;
a plurality of first semiconductor layers vertically stacked and extended outwardly from the first side of the dielectric wall;
a plurality of second semiconductor layers vertically stacked and extended outwardly from the second side of the dielectric wall;
a first gate electrode layer surrounding at least three surfaces of each of the first semiconductor layers, the first gate electrode layer having a first conductivity type;
a second gate electrode layer surrounding at least three surfaces of each of the second semiconductor layers, the second gate electrode layer having a second conductivity type opposite the first conductivity type;
a first bottom dielectric layer disposed between the first fin structure and the first S/D feature; and
a second bottom dielectric layer disposed between the second fin structure and the second S/D feature.

14. The semiconductor device structure of claim 13, wherein the first bottom dielectric layer and the second bottom dielectric layer are separated by the first fin structure.

15. The semiconductor device structure of claim 13, wherein the first bottom dielectric layer and the second bottom dielectric layer are connected.

16. The semiconductor device structure of claim 15, wherein the first bottom dielectric layer and the second bottom dielectric layers are in contact with the dielectric wall.

17. The semiconductor device structure of claim 13, wherein first bottom dielectric layer is separated from the first S/D feature by a first air gap.

18. The semiconductor device structure of claim 17, wherein second bottom dielectric layer is separated from the second S/D feature by a second air gap.

19. A method for forming a semiconductor device structure, comprising:
forming first and second fin structures from a substrate, wherein the first fin structure includes a first plurality of semiconductor layers over a first sacrificial layer, and the second fin structure includes a second plurality of semiconductor layers over a second sacrificial layer, and wherein each of the first and second plurality of semiconductor layers comprises first semiconductor layers and second semiconductor layers;
forming a dielectric wall between the first fin structure and the second fin structure;
forming an insulating material between the second and third fin structures;
forming a sacrificial gate stack over a portion of the first and second fin structure;
selectively removing the first and second sacrificial layers to form an opening;
filling the opening with a bottom dielectric material;
forming a source/drain feature over the bottom dielectric material;
selectively removing the second semiconductor layers of the first and second plurality of semiconductor layers;
forming an interfacial layer (IL) to surround at least three surfaces of the first semiconductor layers of the first and second fin structures and exposed surfaces of the bottom dielectric material; and
forming a gate electrode layer over the IL.

20. The method of claim 19, wherein the source/drain features are deposited so that an air gap is formed between the bottom dielectric material and the source/drain features.
